(19) United States
(12) Patent Application Publication
(10) Pub. No.: US 2026/0072824 A1
(43) Pub. Date: Mar. 12, 2026

(54) MEMORY SYSTEM, OPERATING METHOD THEREOF, AND MEMORY MEDIUM

(71) Applicant: YANGTZE MEMORY TECHNOLOGIES CO., LTD., Wuhan (CN)

(72) Inventors: Xingwei TANG, Wuhan (CN); Lu GUO, Wuhan (CN); Chaofan XIE, Wuhan (CN)

(21) Appl. No.: 19/055,333

(22) Filed: Feb. 17, 2025

(30) Foreign Application Priority Data
Sep. 9, 2024 (CN) 2024112627722

(51) Int. Cl. G06F 12/02; G11C 16/04; G11C 16/10; G11C 16/26

(52) U.S. Cl. CPC G06F 12/0246; G11C 16/0483; G11C 16/10; G11C 16/26

(57) ABSTRACT

According to one aspect, a memory system is provided. The memory system may include a memory device and a memory controller coupled to the memory device. The memory controller may be configured to in response to a power-down during a first programming operation, encode to-be-written data corresponding to the first programming operation to obtain encoded data, and write the encoded data into the memory device. Wherein the to-be-written data is data to be written into the memory device through the first programming operation. An amount of the encoded data is less than an amount of the to-be-written data. In response to a power-on after the power-down, decode the obtained encoded data and the written data corresponding to the first programming operation to obtain at least a portion of error recovery data corresponding to the written data.

### CROSS-REFERENCE TO RELATED APPLICATIONS

This application claims the benefit of priority to Chinese Application No. 2024112627722, filed on Sep. 9, 2024, which is incorporated herein by reference in its entirety.

### TECHNICAL FIELD

Examples of the present disclosure relate to the field of semiconductor technologies, and in particular, to a memory system, an operating method thereof, and a memory medium.

### BACKGROUND

With the development of science and technology, the market size of the integrated circuit industry is getting larger and larger, and the process and technology of the nonvolatile memory device in the whole integrated circuit industry have been developed in recent years. The Not-And (NAND)-type memories have become the mainstream product in the memory market due to their higher memory density, controllable production cost, suitable erase speed and retention characteristics.

The development of the related art of NAND-type memories has made significant advancements. However, there is still significant room for improvement in enhancing the performance of NAND-type memories.

### SUMMARY

In view of this, examples of the present disclosure provide a memory system, an operating method thereof, and a memory medium.

According to one aspect of the present disclosure, a memory system is provided. The memory system may include a memory device and a memory controller coupled to the memory device. The memory controller may be configured to in response to a power-down during a first programming operation, encode to-be-written data corresponding to the first programming operation to obtain encoded data. The memory controller may be configured to write the encoded data into the memory device. The to-be-written data is data to be written into the memory device through the first programming operation. An amount of the encoded data is less than an amount of the to-be-written data. The memory controller may be configured to in response to a power-on after the power-down, decode the obtained encoded data and the written data corresponding to the first programming operation to obtain at least a portion of error recovery data corresponding to the written data.

In some examples, the memory device comprises a plurality of memory cells each having N memory bits. N memory bits of the memory cell correspond to N pages of data, N is an integer greater than 2, and the to-be-written data comprises data to be written into N pages. The memory controller may be configured to perform the logical operation on data to be written into every two pages of N pages to obtain the encoded data.

In some examples, a ratio of the amount of the data to be written into N pages to the amount of the encoded data is N:N-1.

In some examples, the memory controller may be configured to perform an OR logical operation or an AND logical operation on the data to be written into every two pages of N pages to obtain the encoded data. The memory controller may be configured to perform an OR logical operation and an AND logical operation on the encoded data and the written data to obtain the at least portion of error recovery data.

In some examples, the memory controller comprises an error correction encoding module and an error correction decoding module; and the memory controller is configured to: control to disable the error correction encoding module before writing the encoded data into the memory device; and control to disable the error correction decoding module after obtaining the encoded data from the memory device.

In some examples, the memory device may include a plurality of memory cells each having N memory bits, wherein N is an integer greater than 2. The memory device may include a first memory region and second memory region. The memory cells in the first memory region read or write a bit of data in a first mode. The memory cells in the second memory region read or write N bits of data in a second mode. The memory controller may be configured to write the encoded data into the memory device in the first mode. The memory controller may be configured to control the memory device to read the encoded data in the first mode before obtaining the encoded data from the memory device.

In some examples, the memory controller may be configured to control the memory device to re-perform a programming operation with the error recovery data.

In some examples, the memory device comprises a plurality of memory cells that are to be programmed to an intermediate memory state after a first programming operation is performed. Data in the intermediate memory state that is to be programmed to a target memory state after a second programming operation is performed. A threshold voltage distribution width of the intermediate memory state is greater than a threshold voltage distribution width of the target memory state.

In some examples, the memory controller is configured to: obtain the to-be-written data from the memory device before encoding the to-be-written data; and obtain the encoded data and the written data from the memory device before decoding the encoded data and the written data.

In some examples, the memory device comprises a page buffer; the memory controller comprises a buffer; and the memory controller is configured to: obtain original to-be-written data from the buffer before obtaining the to-be-written data; and send the original to-be-written data to the page buffer to generate the to-be-written data corresponding to the first programming operation in the page buffer.

In some examples, the memory controller is configured to: obtain a target reference voltage corresponding to the first programming operation before obtaining the written data; and control the memory device to perform a read operation on the written data with the target reference voltage.

In some examples, the memory controller is configured to: obtain M flip results at M reference read voltages corresponding to at least one codeword formed by a preset number of memory cells. Each of the flip results indicates the number of flipped bits of the at least one codeword in two read results at a first and second read voltage. A difference between the first and second read voltage is less than a preset voltage, and M is an integer greater than or equal to 2. The memory controller may be configured to obtain a predicted valley voltage according to the M flip results and the M reference read voltages in combination with a preset function model. The preset function model represents a relationship between the flip results and the reference read voltages, and the M flip results are all within a preset interval. The memory controller may be configured to determine the target reference voltage based on the predicted valley voltage.

In some examples, the preset function model comprises a quadratic function model, and the quadratic function model comprises the following functional relation:

y=a(x+b)²+c

Where y is a flip result of the M flip results, x is a reference read voltage of the M reference read voltages, b represents a prediction parameter, a is a first parameter, and c is a second parameter.

According to another aspect of the present disclosure, an operating method of a memory system is provided. The method may comprise in response to a power-down during a first programming operation, encoding to-be-written data corresponding to the first programming operation to obtain encoded data. The method may comprise writing the encoded data into a memory device of the memory system, wherein the to-be-written data is data to be written into the memory device through the first programming operation. An amount of the encoded data is less than an amount of the to-be-written data. The method may comprise in response to a power-on after the power-down, decoding the obtained encoded data and the written data corresponding to the first programming operation to obtain at least a portion of error recovery data corresponding to the written data.

In some examples, the memory device comprises a plurality of memory cells each having N memory bits, wherein N memory bits of the memory cell correspond to N pages of data, N is an integer greater than 2. The to-be-written data comprises data to be written into N pages. The encoding the to-be-written data to be written into the memory device corresponding to the first programming operation comprises: performing the logical operation on data to be written into every two pages of N pages to obtain the encoded data.

In some examples, a ratio of the amount of the data to be written into N pages to the amount of the encoded data is N:N-1.

In some examples, the performing the logical operation on data to be written into every two pages of N pages to obtain the encoded data comprises: performing an OR logical operation or an AND logical operation on the data to be written into every two pages of N pages to obtain the encoded data. The decoding the encoded data obtained from the memory device and the written data corresponding to the first programming operation comprises: performing an OR logical operation and an AND logical operation on the encoded data and the written data to obtain the at least the portion of error recovery data.

In some examples, the method further comprises: controlling to disable an error correction encoding module in a memory controller of the memory system before writing the encoded data into the memory device; and controlling to disable an error correction decoding module in the memory controller after obtaining the encoded data from the memory device.

In some examples, the memory device comprises a plurality of memory cells each having N memory bits, wherein N is an integer greater than 2. The memory device comprises a first memory region and a second memory region. The memory cells in the first memory region read or write a bit of data in a first mode. The memory cells in the second memory region read or write N bits of data in a second mode. the writing the encoded data into the memory device of the memory system comprises: writing the encoded data into the memory device in the first mode. The method further comprises: controlling the memory device to read the encoded data in the first mode before obtaining the encoded data from the memory device.

In some examples, the method further comprises: controlling the memory device to re-perform a programming operation with the error recovery data.

In some examples, the memory device comprises a plurality of memory cells that are to be programmed to an intermediate memory state after a first programming operation is performed. Data in the intermediate memory state that is to be programmed to a target memory state after a second programming operation is performed, and wherein a threshold voltage distribution width of the intermediate memory state is greater than a threshold voltage distribution width of the target memory state.

In some examples, the method further comprises: obtaining the to-be-written data from the memory device before encoding the to-be-written data; and obtaining the encoded data and the written data from the memory device before decoding the encoded data and the written data.

In some examples, the method further comprises: obtaining original to-be-written data from a buffer of the memory controller of the memory system before obtaining the to-be-written data; and sending the original to-be-written data to a page buffer of the memory device where the to-be-written data corresponding to the first programming operation is generated.

In some examples, the method further comprises: obtaining a target reference voltage corresponding to the first programming operation before obtaining the written data; and controlling the memory device to perform a read operation on the written data with the target reference voltage.

In some examples, the obtaining a target reference voltage corresponding to the first programming operation comprises: obtaining M flip results at M reference read voltages corresponding to at least one codeword formed by a preset number of memory cells. Each of the flip results indicates the number of flipped bits of the at least one codeword in two read results at a first and second read voltage. A difference between the first and second read voltage is less than a preset voltage, and M is an integer greater than or equal to 2. the obtaining a target reference voltage corresponding to the first programming operation comprises obtaining a predicted valley voltage according to the M flip results and the M reference read voltages in combination with a preset function model. The preset function model represents a relationship between the flip results and the reference read voltages, and the M flip results are all within a preset interval; and determining the target reference voltage based on the predicted valley voltage.

In some examples, the preset function model comprises a quadratic function model, and the quadratic function model comprises the following functional relation:

$$y = {a ( x + b )}^{2} + c$$

Where y is the flip result, x is the reference read voltage, b is to represent a prediction parameter, a is a first parameter, and c is a second parameter.

According to another aspect of the present disclosure, a memory medium storing executable instructions thereon is provided, the executable instructions, when executed, implement the operations of the operating method according to any one of the second aspect.

According to the examples of the present disclosure, the to-be-written data corresponding to the first programming operation is encoded to obtain the encoded data. An amount of the encoded data is less than an amount of the to-be-written data. The encoded data is written into the memory device to obtain the error recovery data required for re-performing the programming operation when the power-on after the power-down. In this way, on one hand, the requirement on the capacity of the capacitor is effectively reduced by reducing the amount of data written to the memory device during the power-down protection. on the other hand, when the power-on after the power-down, at least part of the error recovery data is obtained by decoding the encoded data and the written data corresponding to the first programming operation, which can ensure the data integrity when the first programming operation process suffers from the power-down and reduce the risk of failure of the overall programming operation, thereby improving the reliability of the programming operation.

### BRIEF DESCRIPTION OF THE DRAWINGS

In the drawings, like reference numbers refer to like or similar parts or elements throughout the several drawings unless otherwise specified. These drawings are not necessarily drawn to scale. It should be understood that these drawings depict only some implementations disclosed in accordance with the present disclosure and should not be considered as limiting the scope of the present disclosure.

FIG. 1 is a schematic diagram of an example system with a memory system according to an example of the present disclosure;

FIG. 2A is a schematic diagram of an example memory card with a memory system according to an example of the present disclosure;

FIG. 2B is a schematic diagram of an example solid state drive with a memory system according to an example of the present disclosure;

FIG. 3 is a schematic diagram of an example memory device comprising a peripheral circuit according to an example of the present disclosure;

FIG. 4 is a schematic cross-sectional view of a memory cell array comprising a NAND-type memory string according to an example of the present disclosure;

FIG. 5 is a schematic diagram of an example memory device comprising a memory cell array and a peripheral circuit according to an example of the present disclosure;

FIG. 6A is a schematic diagram of threshold voltage distribution after a QLC memory cell performs a first programming operation according to an example of the present disclosure;

FIG. 6B is a schematic diagram of threshold voltage distribution after a QLC memory cell performs a second programming operation according to an example of the present disclosure;

FIG. 7 is a schematic diagram of a composition structure of an example system with a memory system according to an example of the present disclosure;

FIG. 8 is a schematic diagram of a threshold voltage distribution corresponding to a memory cell comprising 4 memory bits according to an example of the present disclosure;

FIG. 9 is a schematic diagram of a threshold voltage distribution of a memory cell when flip results are obtained according to an example of the present disclosure;

FIG. 10 is a schematic diagram of a preset function model according to an example of the present disclosure;

FIG. 11 is a schematic diagram of determining a preset interval according to an example of the present disclosure;

FIG. 12 is a first schematic diagram of obtaining a reference read voltage according to an example of the present disclosure;

FIG. 13 is a second schematic diagram of obtaining a reference read voltage according to an example of the present disclosure;

FIG. 14 is a third schematic diagram of obtaining a reference read voltage according to an example of the present disclosure;

FIG. 15 is a fourth schematic diagram of obtaining a reference read voltage according to an example of the present disclosure;

FIG. 16 is a first schematic flowchart of an operating method of a memory system according to an example of the present disclosure;

FIG. 17 is a second flowchart of an operating method of a memory system according to an example of the present disclosure;

FIG. 18 is a schematic diagram of a composition structure of a memory medium according to an example of the present disclosure.

### DETAILED DESCRIPTION

Example implementations disclosed in the present disclosure will be described in more detail below with reference to the accompanying drawings. Although example implementations of the present disclosure are shown in the accompanying drawings, it is to be understood that the present disclosure may be implemented in various forms and should not be limited to the example implementations set forth herein. Rather, these implementations are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; for example, not all features of the actual example are described here, and well-known functions and structures are not described in detail.

In addition, the drawings are merely schematic illustrations of the present disclosure, and are not necessarily drawn to scale. Like reference numerals in the drawings refer to the same or similar parts, and repeated description thereof will be omitted. Some of the block diagrams shown in the drawings are functional entities and do not necessarily have to correspond to physically or logically separate entities. These functional entities may be implemented in software form, or implemented in one or more hardware modules or integrated circuits, or implemented in different networks and/or processor apparatuses and/or microcontroller apparatuses.

The flowchart shown in the drawings is merely example and not necessarily all operations. For example, some operations may be further decomposed, and some operations may be combined or partially combined, so the actual execution sequence may be changed according to actual conditions.

A term used herein is for the purpose of describing a particular example only and is not to be considered as limitation of the present disclosure. As used herein, the singular forms “a”, “an” and “said/the” are intended to comprise the plural forms as well, unless the context clearly dictates otherwise. It should also be understood that the terms “consists of” and/or “comprising”, when used in this description, identify the presence of stated features, integers, steps, operations, elements and/or parts, but do not exclude the presence of one or more other features, integers, steps, operations, elements, parts and/or groups. As used herein, the term “and/or” comprises any and all combinations of the associated listed items.

Memory devices in examples of the present disclosure comprise but are not limited to a three-dimensional NAND-type memory, and for case of understanding, a three-dimensional NAND-type memory is used as an example for illustration.

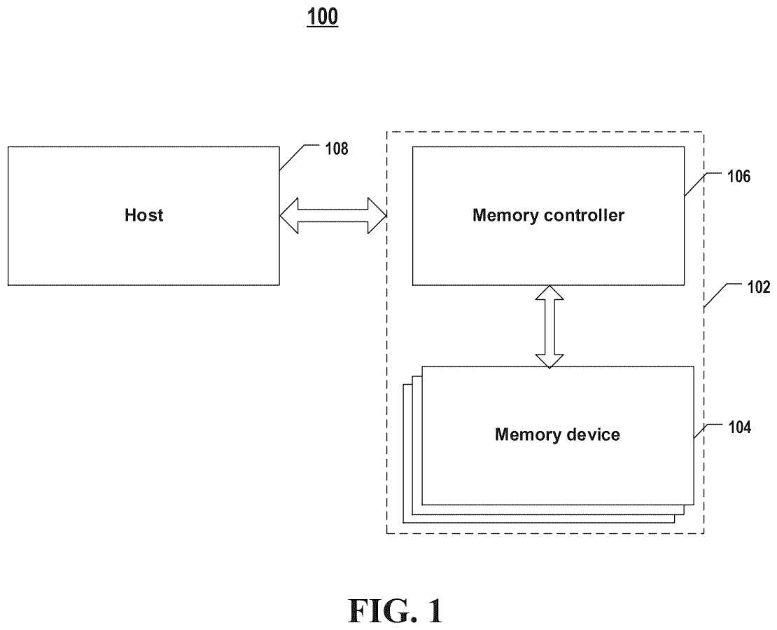

FIG. 1 illustrates a block diagram of an example system 100 with memory devices in accordance with some aspects of the present disclosure. The system 100 may be a mobile phone, a desktop computer, a laptop computer, a tablet, a vehicle computer, a gaming console, a printer, a positioning device, a wearable electronic device, a smart sensor, a Virtual Reality (VR) device, an Augment Reality (AR) device, or any other suitable electronic devices having memory therein. As shown in in FIG. 1, system 100 may comprise a host 108 and a memory system 102, and the memory system 102 has one or more memory devices 104 and a memory controller 106. The host 108 may be a processor of an electronic device (e.g., a Central Processing Unit (CPU)) or a System of Chip (SoC) (e.g., an Application Processor (AP)). The host 108 may be configured to send data to or receive data from the memory device 104.

According to some implementations, the memory controller 106 is coupled to the memory device 104 and the host 108 and is configured to control memory device 104. The memory controller 106 may manage data stored in the memory device 104 and communicate with the host 108. In some implementations, the memory controller 106 is designed to operate in low duty cycle environments, e.g., Secure Digital (SD) card, Compact Flash (CF) card, Universal Serial Bus (USB) flash drive, or other media for use in electronic devices such as personal computer, digital camera, mobile phone, etc.

In some implementations, the memory controller 106 is designed to operate in high duty cycle environment Solid State Drive (SSD) or Embedded Multi Media Card (eMMC), where SSD or eMMC is employed as data memory device for mobile devices such as smartphone, tablet computer, laptop computer, enterprise memory array, etc.

The memory controller 106 may be configured to control operations of the memory device 104, e.g., read, erase and programming operations. Memory controller 106 may also be configured to manage various functions related to data stored or to be stored in the memory device 104, comprising but not limited to bad block management, garbage collection, logical-to-physical address translation, wear leveling, etc. In some implementations, the memory controller 106 is also configured to process error correction code related to data read from or written to the memory device 104.

The memory controller 106 may also perform any other suitable functions, e.g., formatting the memory device 104. The memory controller 106 may communicate with external devices (e.g., the host 108) according to a particular communication protocol. For example, the memory controller 106 may communicate with external devices through at least one of various interface protocols, such as USB protocol, MMC protocol, Peripheral Component Interconnection (PCI) protocol, PCI Express (PCI-E) protocol, Advanced Technology Attachment (ATA) protocol, Serial ATA protocol, Parallel ATA protocol, Small Computer Small Interface (SCSI) protocol, Enhanced Small Disk Interface (ESDI) protocol, Integrated Drive Electronics (IDE) protocol, Firewire protocol, etc.

The memory controller 106 and one or more memory devices 104 may be integrated into various types of memory devices, e.g., included in the same package (e.g., Universal Flash Storage (UFS) package or eMMC package). For example, the memory system 102 may be implemented and packaged into different types of end electronic products.

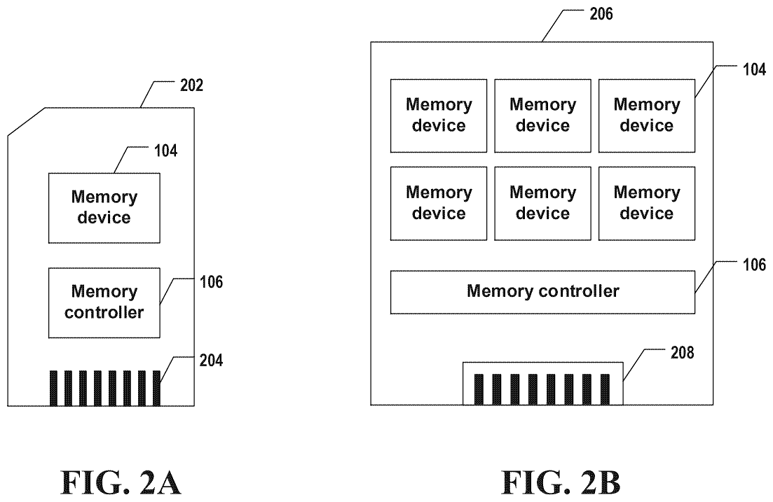

In one example as shown in FIG. 2A, the memory controller 106 and a single memory device 104 may be integrated into a memory card 202. The memory card 202 may comprise a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. The memory card 202 may further comprise a memory card connector 24 coupling the memory card 202 with a host (e.g., the host 108 in FIG. 1).

In another example as shown in FIG. 2B, the memory controller 106 and multiple memory devices 104 may be integrated into a SSD 206. The SSD 206 may further comprise an SSD connector 208 coupling the SSD 206 with a host (e.g., the host 108 in FIG. 1). In some implementations, the memory capacity and/or operating speed of the SSD 206 is greater than the memory capacity and/or operating speed of the memory card 202.

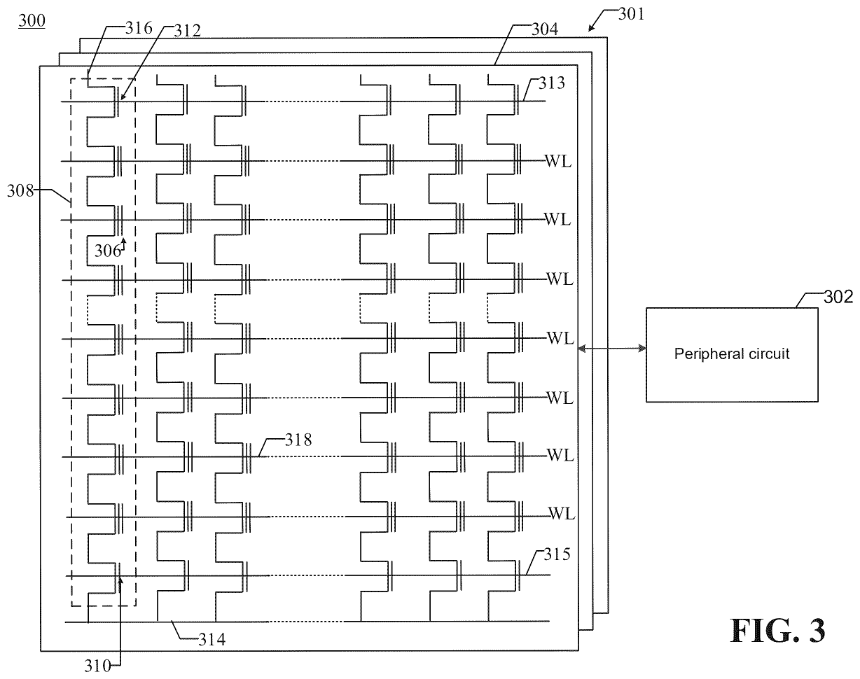

FIG. 3 illustrates a schematic circuit diagram of an example memory device 300 comprising peripheral circuitry according to some aspects of the present disclosure. The memory device 300 may be an example of a memory device 104 in FIG. 1. The memory device 300 may comprise a memory cell array 301 and a peripheral circuit 302 coupled to the memory cell array 301. Taking the memory cell array 301 being a three-dimensional NAND-type memory cell array as an example for illustration, where memory cells 306 are NAND-type memory cells, and memory cells 306 are provided in the form of an array of memory strings 308, each memory string 308 extends vertically over a substrate (not shown). In some implementations, each memory string 308 comprises multiple memory cells 306 coupled in series and stacked vertically. Each memory cell 306 may retain a continuous analog value, e.g., voltage or charge, depending on the number of electrons trapped within the region of the memory cell 306. Each memory cell 306 may be a “floating gate” type memory cell comprising a floating gate transistor, or a “charge trap” type memory cell comprising a charge trap transistor.

In some implementations, each memory cell 306 is a Single-Level Cell (SLC) that has two possible memory states and may thus store one bit of data. For example, a first memory state of “O” may correspond to a first voltage range, and a second memory state of “1” may correspond to a second voltage range. In some implementations, each memory cell 306 is a Multi-Level Cell (MLC) capable of storing more than a single bit of data in more than four memory states. For example, an MLC may store two bits per cell (also known as a Double-Level Cell), three bits per cell (also known as a Trinary-Level Cell (TLC)), four bits per cell (also known as a Quad-Level Cell (QLC)), five bits per cell (also known as a Penta-level Cell (PLC)), or more than five bits per cell. Each MLC can be programmed to assume a range of possible nominal memory values. In one example, if each MLC stores two bits of data, the MLC can be programmed to assume one of three possible program levels from the erased state through writing one of three possible nominal memory values into the cell, a fourth nominal memory value may be employed for the erase state.

It is to be noted that the memory state mentioned here is also the memory state of the memory cell mentioned in the present disclosure. Different memory cells have different numbers of memory states. e.g., a SLC type memory cell has two memory states (e.g., two memory states), where the two memory states comprise a program state and an erase state. As another example, an MLC type memory cell has four memory states, where the four memory states comprise one erase state and three program states. As yet another example, a TLC type memory cell has eight memory states, where the eight memory states comprise one erase state and seven program states. In some implementation, the QLC type memory cell has sixteen memory states, where the sixteen memory states comprise one erase state and fifteen program states.

As shown in FIG. 3, each memory string 308 may comprise a bottom select gate (BSG) 310 (also referred to as a source side select gate) at its source terminal and a top select gate (TSG) 312 (also referred to as a drain side select gate) at its drain terminal. BSG 310 and TSG 312 may be configured to activate the selected memory cell string 308 during read operation and programming operation. In some implementations, the sources of memory strings 308 in a same memory block 304 are coupled through a same source line (SL) 314 (e.g., a common SL). For example, according to some implementations, all memory strings 308 in a same memory block 304 have an array common source (ACS). According to some implementations, TSG 312 of each memory string 308 is coupled to a corresponding bit line (BL) 316 from which data may be read or written via an output bus (not shown). In some implementations, each memory string 308 is configured to be selected or deselected through applying a select voltage (e.g., above the threshold voltage of a transistor with a TSG 312) or a deselect voltage (e.g., 0V) to the corresponding TSG 312 via one or more TSG lines 313 and/or applying a select voltage (e.g., above the threshold voltage of a transistor with a BSG 310) or a deselect voltage (e.g., 0V) to the corresponding BSG 310 via one or more BSG lines 315.

As also shown in FIG. 3, a memory string 308 may be organized into multiple memory blocks 304, and each of the multiple memory blocks 304 may have a common source line 314 (e.g., coupled to ground). In some implementations, each memory block 304 is the basic data unit for an erase operation, e.g., all memory cells 306 on the same memory block 304 are erased simultaneously. To erase the memory cell 306 in the selected memory block 304, the source line 314 coupled to the selected memory block 304 and to the unselected memory blocks 304 in the same plane as the selected memory block 304 may be biased with an erase voltage (Vers) (e.g., a high positive voltage (e.g., 20V or higher)). It is to be understood that, in some examples, erase operations may be performed at the half-memory block level, at the quarter-memory block level, or at a level with any suitable number of memory blocks or any suitable fraction of memory blocks. The memory cells 306 of adjacent memory strings 308 may be coupled through a word line 318 that selects which row of memory cells 306 is affected by read and programming operations.

Referring to FIG. 3, each of the multiple memory cells 306 is coupled to a corresponding word line 318, and each memory string 308 is coupled to a corresponding bit line 316 through a corresponding select transistor (e.g., top select transistor (TSG) 312).

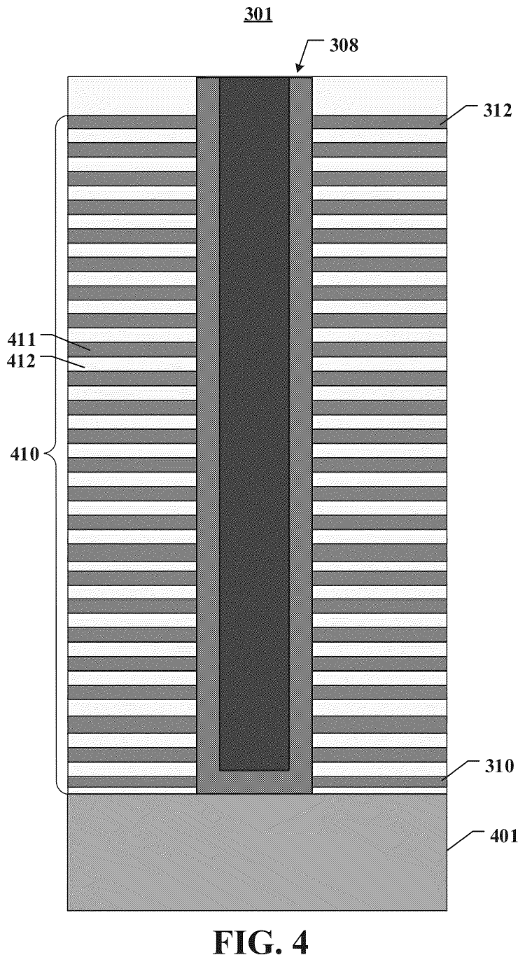

FIG. 4 illustrates a schematic cross-sectional view of an example memory cell array 301 comprising memory strings 308, e.g., NAND, according to some aspects of the present disclosure. As shown in FIG. 4, the NAND memory cell array 301 may comprise a stacked structure 410, and the stacked structure 410 comprises multiple gate layers 411 and multiple insulating layers 412 alternately stacked in sequence, and the channel structure vertically penetrating through the gate layers 411 and the insulating layers 412, wherein the channel structure is coupled to each gate layer to form a memory cell, and the channel structure is coupled to multiple gate layers in the stacked structure 410 to form the memory string 308. Gate layers 411 and the insulating layers 412 may be stacked alternately, and two adjacent gate layers 411 are separated by an insulating layer 412.

A constituent material of the gate layer 411 may comprise a conductive material. The conductive material comprises, but are not limited to, tungsten (W), cobalt (Co), copper (Cu), aluminum (Al), polysilicon, doped silicon, silicide, or any combination thereof. In some examples, each gate layer 411 comprises a metal layer, e.g., a tungsten layer. In some examples, each gate layer 411 comprises a doped polysilicon layer. Each gate layer 411 may comprise a control gate surrounding a memory cell. A gate layer 411 at the top of a stacked structure 410 may extend laterally as a top select gate line, a gate layer 411 at the bottom of a stacked structure 410 may extend laterally as a bottom select gate line, and a gate layer 411 extending laterally between a top select gate line and a bottom select gate line may serve as a word line layer.

In some examples, a stacked structure 410 may be disposed on a substrate 401. The substrate 401 may comprise silicon (e.g., monocrystalline silicon), silicon germanium (SiGe), gallium arsenide (GaAs), germanium (Ge), silicon-on-insulator (SOI), germanium-on-insulator (GOI), or any other appropriate material.

In some examples, a memory string 308 comprises a channel structure extending vertically through the stacked structure 410. In some implementations, a channel structure comprises a channel hole filled with semiconductor material(s) (e.g., as a semiconductor channel) and dielectric material(s) (e.g., as a memory film). In some implementations, a semiconductor channel comprises silicon, e.g., polysilicon. In some implementations, a memory film is a composite dielectric layer comprising a tunneling layer, a memory layer (also referred to as a “charge trapping/memory layer”), and a blocking layer. A channel structure may have a cylindrical shape (e.g., a pillar shape). According to some implementations, a semiconductor channel, a tunneling layer, a memory layer and a blocking layer are radially arranged in this order from the center of the pillar toward the outer surface of the pillar. A tunneling layer may comprise silicon oxide, silicon oxynitride, or any combination thereof. A memory layer may comprise silicon nitride, silicon oxynitride, or any combination thereof. A blocking layer may comprise silicon oxide, silicon oxynitride, a high-k (high-k) dielectric, or any combination thereof. In an example, a memory film may comprise a composite layer of silicon oxide/silicon oxynitride/silicon oxide (ONO).

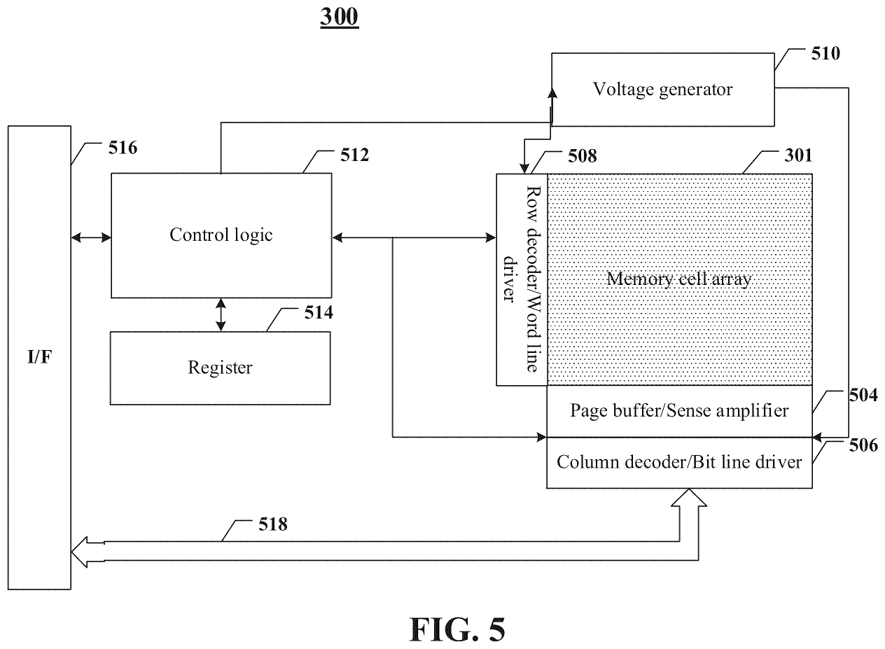

Referring back to FIG. 3, the peripheral circuit 302 may be coupled to the memory cell array 301 through bit line 316, word line 318, source line 314, BSG line 315, and TSG line 313. The peripheral circuit 302 may comprise any suitable analog, digital, and mixed-signal circuitry for facilitating operation of the memory cell array 301 through applying a voltage signal and/or a current signal to and sensing voltage signal and/or current signal from each target memory cell 306 via bit line 316, word line 318, source line 314, BSG line 315, and TSG line 313. The peripheral circuit 302 may comprise various types of peripheral circuits formed with metal-oxide-semiconductor (MOS) technology. For example, FIG. 5 illustrates some example peripheral circuits, the peripheral circuit comprises page buffer/sense amplifier 504, column decoder/bit line driver 506, row decoder/word line driver 508, voltage generator 510, control logic 512, register 514, interface 516 and data bus 518. It is to be understood that in some examples, additional peripheral circuits not shown in FIG. 5 may also be included.

The page buffer/sense amplifier 504 may be configured to read data from and program (write) data to the memory cell array 301 according to control signals from the control logic 512. In one example, the page buffer/sense amplifier 504 may store program data (written data) to be programmed into the memory cell array 301. In another example, the page buffer/sense amplifier 504 may perform a program verify operation to ensure that data has been correctly programmed into the memory cell 306 coupled to selected word line 318. In yet another example, the page buffer/sense amplifier 504 may also sense a low power signal from the bit line 316 representing a data bit stored in the memory cell 306 and amplify a small voltage swing to a recognizable logic level during a read operation. The column decoder/bit line driver 506 may be configured to be controlled by the control logic 512 and to select one or more memory strings 308 through applying a bit line voltage generated from the voltage generator 510.

The row decoder/word line driver 508 may be configured to be controlled by the control logic 512 and to select/deselect the memory block 304 of the memory cell array 301 and to select/deselect the word line 318 of the memory block 304. The row decoder/word line driver 508 may also be configured to drive the word line 318 with a word line voltage generated from the voltage generator 510. In some implementations, the row decoder/word line driver 508 may also select/deselect and drive the BSG line 315 and the TSG line 313. As described in detail below, the row decoder/word line driver 508 is configured to perform programming operations on the memory cells 306 coupled to the selected word line(s) 318. The voltage generator 510 may be configured to be controlled by the control logic 512, and generate word line voltage (e.g., read voltage, program voltage, pass voltage, channel boost voltage, verification voltage, etc.), bit line voltage and source line voltage to be supplied to the memory cell array 301.

The control logic 512 may be coupled to each of other parts of the peripheral circuit described above, and configured to control operations of each of the other units of the peripheral circuit. The register 514 may be coupled to the control logic 512 and comprise status register, command register and address register for storing status information, command operation code (OP code) and command address for controlling operations of each of the peripheral circuits. The interface 516 may be coupled to the control logic 512 and act as a control buffer to buffer and relay control commands received from a host (not shown) to control logic 512 and to buffer and relay status information received from the control logic 512 to the host. The interface 516 may also be coupled to column decoder/bit line driver 506 via the data bus 518 and act as a data I/O interface and data buffer to buffer and relay data to/from the memory cell array 301.

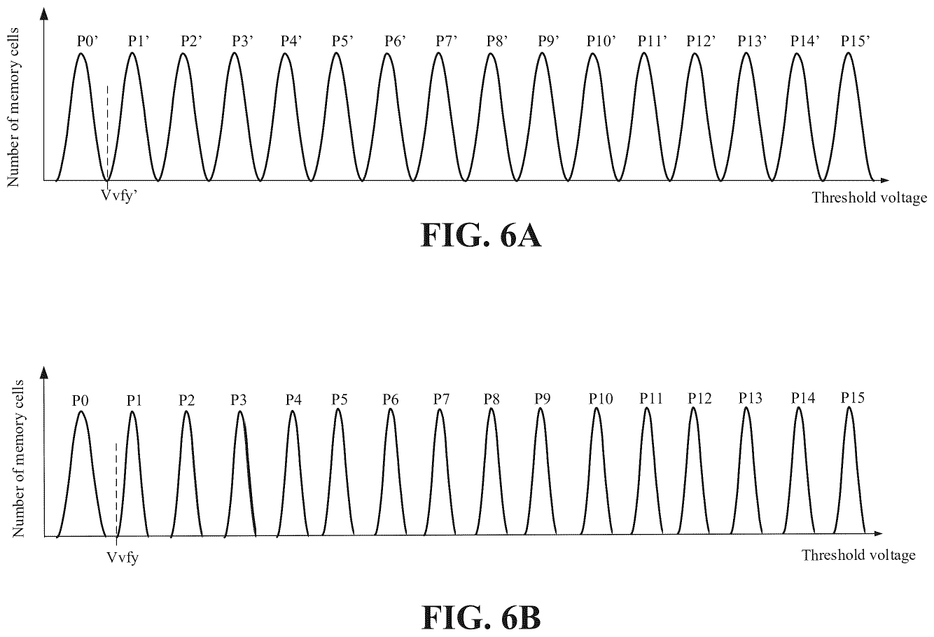

In some examples, when the programming operation is performed on the memory cell in the memory cell array 301, a multi-pass programming operation may be employed to increase read margin. Taking the memory cell in the memory cell array 301 being a QLC type of memory cell as an example for description, when a 16-16 scheme is employed to perform a two-pass programming operation on the QLC, after performing the first programming operation on the QLC memory cell, the threshold voltage distribution width shown in FIG. 6A may be formed. Further, as shown in FIG. 6B, after performing the second programming operation on the QLC memory cell on which the first programming operation has been performed in FIG. 6A, the formed threshold voltage distribution width may be finely narrowed. Thus, the first programming operation may be referred to as a coarse programming operation and the second programming operation may be referred to as a fine programming operation.

For example, the first programming operation or the second programming operation may be performed on the QLC memory cell based on Incremental Step Pulse Program (ISPP). For example, the QLC memory cell is controlled to reach a predetermined threshold voltage interval after performing the first programming operation and the second programming operation, respectively, by controlling the step size of the ISPP. For example, the first verification voltage Vvfy′ may be employed to verify the target threshold voltage interval P1′ that the QLC memory cell reaches after the first programming operation, and the second verification voltage Vvfy may be employed to verify the target threshold voltage interval P1 that the QLC memory cell reaches after the second programming operation. Optionally, the first verification voltage Vvfy′ is less than the second verification voltage Vvfy.

By a coarse to fine programming method, the two-pass programming operation described above achieves high-precision voltage regulation, reduces programming errors, and improves the reliability of data memory. However, in the first programming (coarse programming) operation phase, the threshold voltage distribution of the memory cell is wider (as shown in FIG. 6A), so it is difficult to accurately read the coarse programming data written into the memory cell in the first programming operation phase. In addition, in the data retention scenario, the threshold voltage of the memory cell may be shifted over time or when the environment changes, which further increases the difficulty of accurately reading the coarse programming data. If power-down occurs during the first programming operation phase, the data may not be written timely, thus resulting in data loss.

In order to solve this problem, power loss protection (PLP) is usually provided through a capacitor. Since the amount of to-be-written data is large and the writing time is long, a capacitor with large capacity needs to be set to provide a longer protection time, so as to ensure that all the to-be-written data is completely written into the NAND during power-down, thereby preventing data loss. However, the capacitor with large capacity not only increases the physical size and cost, but also presents challenges to the overall design of memory devices, generally memory devices such as memory devices, memory systems, and the like. Therefore, how to improve the reliability of the memory devices without increasing the burden of the product becomes an urgent problem to be solved.

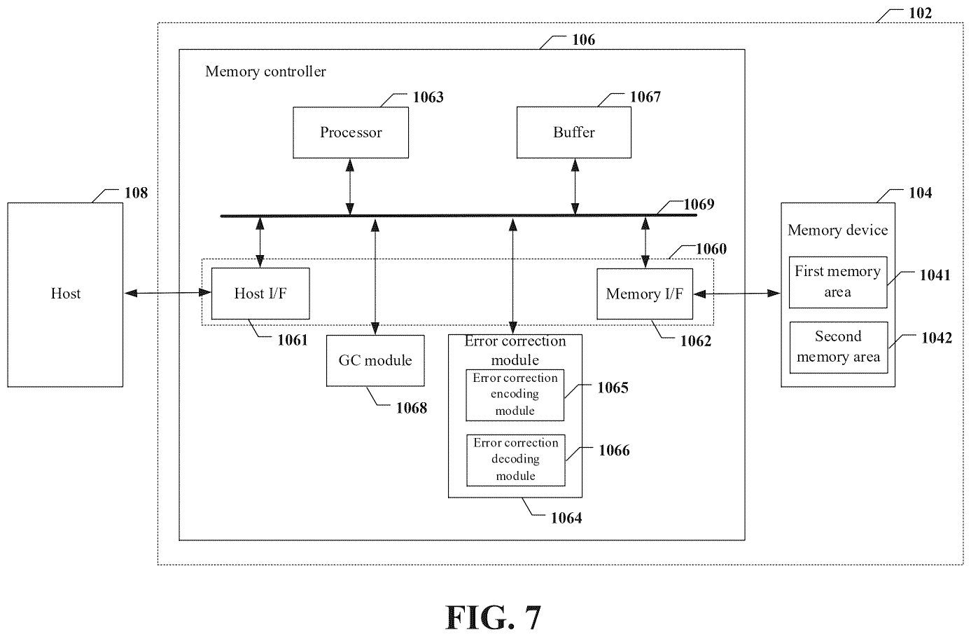

Based on one or more of the foregoing problems, according to a first aspect, an example of the present disclosure provides a memory system. As shown in FIG. 7, the memory system 102 comprises: a memory device 104; a memory controller 106 coupled to the memory device 104 and configured to: in response to a power-down during a first programming operation, encode to-be-written data corresponding to the first programming operation to obtain encoded data, and write the encoded data into the memory device, wherein the to-be-written data is data to be written into the memory device through the first programming operation, and the amount of the encoded data is less than the amount of the to-be-written data; and in response to a power-on after the power-down, decode the obtained encoded data and the written data corresponding to the first programming operation to obtain at least a portion of error recovery data corresponding to the written data.

In some examples, the memory device comprises a plurality of memory cells that is to be programmed to an intermediate memory state after a first programming operation is performed, and data in the intermediate memory state is programmed to a target memory state after performing a second programming operation, and wherein a threshold voltage distribution width of the intermediate memory state is greater than a threshold voltage distribution width of the target memory state.

Here, the first programming operation may be referred to as a coarse programming operation, and the second programming operation may be referred to as a fine programming operation. Taking the QLC memory cell as an example, the threshold voltage distribution width of the QLC memory cell after the first programming operation is shown in FIG. 6A, and the threshold voltage distribution width of the QLC memory cell on which the first programming operation has been performed after the second programming operation is shown in FIG. 6B. For example, the threshold voltage distribution width of the intermediate memory state as shown in FIG. 6A is greater than the threshold voltage distribution width of the target memory state shown in FIG. 6B.

In some examples, the memory controller is further configured to: control the memory device to re-perform a programming operation with the error recovery data.

According to the examples of the present disclosure, the to-be-written data corresponding to the first programming operation is encoded to obtain the encoded data, wherein an amount of the encoded data is less than an amount of the to-be-written data, and the encoded data is written into the memory device to obtain the error recovery data required for re-performing the programming operation when the power-on after the power-down. In this way, on the one hand, by reducing the amount of data written to the memory device during the power-down protection, the requirement on the capacity of the capacitor is effectively reduced; on the other hand, when the power-on after the power-down, at least part of the error recovery data is obtained by decoding the encoded data and the written data corresponding to the first programming operation, which can ensure the data integrity when the first programming operation process suffers from the power-down and reduces the risk of failure of the overall programming operation, thereby improving the reliability of the programming operation.

FIG. 7 is a schematic diagram of a composition structure of an example system with a memory system according to an example of the present disclosure. As shown in FIG. 7, the memory controller 106 is coupled to the memory device 104, and is configured to control the memory device 104 to perform operations such as read, write and erase operation. The memory controller 106 may comprise an interface 1060 and a processor 1063, wherein the interface 1060 is configured for data interaction with external devices, and the processor 1063 is configured to control the memory controller 106 and the memory device 104 as a whole.

In some examples, the interface 1060 may comprise a host interface (I/F) 1061 and a memory interface (I/F) 1062; wherein the host interface 1061 is a connection interface connecting the host 108 and the memory controller 106, and allows the host and the memory controller to communicate according to a particular protocol, send read and write requests, and perform other operations. The memory interface 1062 is a connection interface between the memory controller 106 and the memory device 104, and configured to implement data transmission between the memory controller 106 and the memory device 104.

In some examples, the processor 1063 may comprise one or more units having a logical operation capability, for example, a Central Processing Unit (CPU) and/or a Microcontroller Unit (MCU), etc.

In some examples, the memory controller 106 may further comprise an error correction module 1064, a buffer 1067, a garbage collection (GC) module 1068, and a bus 1069, etc. The error correction module 1064 may further comprise an error correction encoding module 1065 and an error correction decoding module 1066; the error correction encoding module 1065 is configured to encode the to-be-stored data to obtain check data, and the error correction decoding module 1066 is configured to decode the check data to detect and correct possible error data in a data transmission process. The buffer 1067 is configured to cache data. In some examples, the buffer 1067 may be a volatile memory device with a relatively fast read/write speed, such as a Static Random-Access Memory (SRAM) and/or a Dynamic Random Access Memory (DRAM). The garbage collection module 1068 is configured to read out valid data on some memory blocks after the memory space of the memory device reaches a certain threshold, rewrite and then label the memory blocks to obtain new backup memory blocks.

In some examples, the memory controller 106 may further comprise other modules not listed, such as a wear leveling module, a bad block management module, an SLC caching module, and the like.

In some examples, the memory device may comprise a NAND-type memory. The structure of the memory device may be referred to FIG. 3, and not described herein again.

Generally, the power-down is divided into two types: one is normal power-down, and the other is abnormal power-down. The so-called normal power-down is that, before power-down, the host 108 notifies the memory system 102 through a command, and the memory system 102 mainly performs the following operations: (1) flushing the user data cached in the buffer into the memory device 104; (2) flushing the mapping table into the memory device 104; and (3) writing the block information of the memory device into the memory device 104 (such as a memory device whose block is currently written into and the location of the block of the memory device being written, the memory devices whose blocks have been written, the memory devices whose blocks are also invalid, etc.). The host 108 will not actually stop supplying power to the memory system 102 until the memory system 102 completes the above operations. Based on this, the normal power-down would not cause the data to be lost, and after power-on again, the memory system 102 only needs to reload related information saved before power-down, and can continue to work following the status before power-down. The abnormal power-down is that, the memory system 102 is powered down without receiving a power-down notification from the host 108; or is powered down after receiving a power-down notification from the host 108, but has not performed those operations mentioned above. Abnormal power-down may be due to power failure, sudden power loss, or battery depletion, which may cause data loss or damage.

It should be noted that the power-down in the examples of the present disclosure refers to abnormal power-down condition.

In some examples, the memory device comprises a plurality of memory cells each having N memory bits, wherein N memory bits of the memory cell correspond to N pages of data, N is an integer greater than 2, and the to-be-written data comprises data to be written into N pages; and the memory controller is configured to: perform the logical operation on data to be written into every two pages of N pages to obtain the encoded data.

In some examples, each memory block may be coupled to a plurality of word lines, and a plurality of memory cells coupled to each word line form one or more pages, wherein a number of pages is related to a number of memory bits included in the memory cell. For example, a plurality of MLCs coupled to each word line form two pages, and a plurality of TLCs coupled to each word line form three pages. In some examples, a plurality of QLC memory cells (with memory bits of four) coupled to each word line form four pages.

For example, the memory device comprises a plurality of memory cells with memory bits of four, four memory bits of the memory cell correspond to data of four pages, and the to-be-written data comprises data to be written into the four pages; and the memory controller is configured to: perform the logical operation on data to be written into every two pages of the four pages to obtain the encoded data.

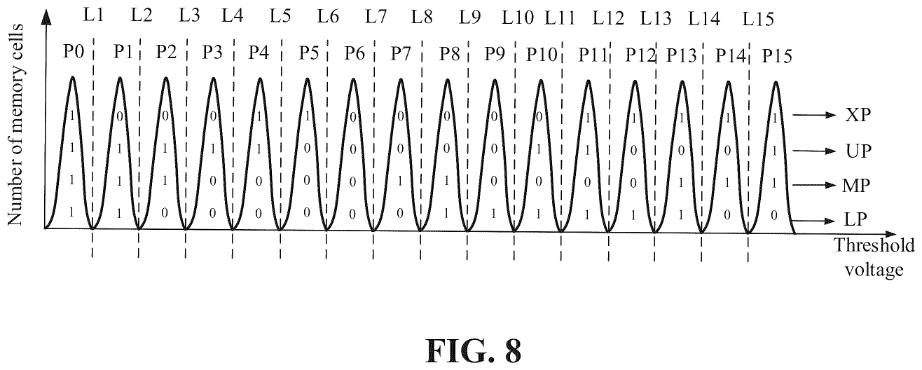

For example, when a number of memory bits of a memory cell comprises four bits, a corresponding memory state comprises a zeroth state to a fifteenth state, and referring to FIG. 8, the 16 states are a zeroth state (also referred to as an erase state) P0, a first state (also referred to as a first memory state) P1, a second state (also referred to as a second memory state) P2 . . . , a fifteenth state (also referred to as a fifteenth memory state) P15, respectively, and binary data corresponding to the 16 states are 1111, 0111, 0110 . . . , respectively. Correspondingly, the memory device comprises four pages, namely Lower page (LP), Middle Page (MP), Upper Page (UP), and Extra Page (XP), respectively. Here, four memory bits corresponding to the 16 states are stored in a lower page, a middle page, an upper page, and an extra page, respectively.

Taking the memory cell shown in FIG. 8 as an example, the four-bit memory cell reads its stored data with sixteen states of four bits by a 15-level read voltage (the first level read voltage L1, the second level read voltage L2, the third level read voltage L3, the fourth level read voltage L4, the fifth level read voltage L5, the sixth level read voltage L6, the seventh level read voltage L7, the eighth level read voltage L8, the ninth level read voltage L9, the tenth level read voltage L10, the eleventh level read voltage L11, the twelfth level read voltage L12, the thirteenth level read voltage L13, the fourteenth level read voltage L14, and the fifteenth level read voltage L15 shown in FIG. 8).

For example, each page corresponds to a Multi-Level Read voltage, as shown in FIG. 8, the binary data corresponding to the lower page is 1100000011111100, and the corresponding second level read voltage L2, the eighth level read voltage L8, and the fourteenth level read voltage L14 are required to read the lower page. The binary data corresponding to the middle page is 1110000110000111, and the corresponding third level read voltage L3, the seventh level read voltage L7, the ninth level read voltage L9, and the thirteenth level read voltage L13 are required to read the middle page. The binary data corresponding to the upper page is 1111100000110001, and the corresponding fifth level read voltage L5, the tenth level read voltage L10, the twelfth level read voltage L12, and the fifteenth level read voltage L15 are required to read the upper page. The binary data corresponding to the extra page is 1000110000011111, and the corresponding first level read voltage L1, the fourth level read voltage L4, the sixth level read voltage L6, and the eleventh level read voltage L11 are needed to read the extra page.

In some examples, a ratio of the amount of the data to be written into N pages to the amount of the encoded data is N:N-1.

Taking N equal to 4 as an example, a ratio of the amount of the data to be written into four pages to the amount of the encoded data is 4:3.

In some examples, the memory controller is configured to: perform the logical operation on the data to be written into every two pages of the four pages (LP, MP, UP, and XP) to obtain encoded data. For example, the logical operation are performed on the data to be written into LP and the data to be written into MP to obtain first encoded data Parity 1, the logical operation are performed on the data to be written into MP and the data to be written into UP to obtain second encoded data Parity2, and the logical operation are performed on the data to be written into UP and the data to be written into XP to obtain third encoded data Parity3. It can be understood that, by performing the logical operation on data to be written into the four pages, three encoded data (the first encoded data Parity 1, the second encoded data Parity2, and the third encoded data Parity3) are obtained.

In other examples, the logical operation are performed on the data to be written into LP and the data to be written into MP to obtain the first encoded data, the logical operation are performed on the data to be written into LP and the data to be written into UP to obtain the second encoded data, and the logical operation are performed on the data to be written into UP and the data to be written into XP to obtain the third encoded data.

In some examples, taking QLC as an example, the amount of the data to be written into each page is 16k bytes, and the amount of each encoded data is 16k bytes, so the ratio of the amount of the data to be written into the four pages to the amount of the encoded data is (4×16k):(3×16k)=4:3.

It should be noted that, the size of the amount of the data to be written into each page is merely an example, and the scope of the present disclosure should not be limited herein.

In some examples, the logical operation may be an OR logical operation or an AND logical operation.

In some examples, with reference to FIG. 5 and FIG. 7, the memory device 104 comprises a page buffer (see the page buffer 504 shown in FIG. 5); and the memory controller 106 comprises a buffer 1067 (see the buffer 1067 shown in FIG. 7); and the memory controller 106 is configured to: obtain the original to-be-written data from the buffer 1067 before obtaining the to-be-written data; and send the original to-be-written data to the page buffer 504 where the to-be-written data corresponding to the first programming operation is generated.

Here, taking the QLC as an example for illustration, the buffer 1067 of the memory controller 106 stores the original to-be-written data, the original to-be-written data corresponding to the LP is denoted as LP0, the original to-be-written data corresponding to the MP is denoted as MP0, the original to-be-written data corresponding to the UP is denoted as UP0, and the original to-be-written data corresponding to the XP is denoted as XP0.

For example, the memory controller 106 is configured to: obtain the original to-be-written data LP0, MP0, UP0, and XP0 from the buffer 1067 before obtaining the to-be-written data; and send the original to-be-written data LP0, MP0, UP0, and XP0 to the page buffer 504; and read the original to-be-written data stored in the page buffer 504 from the page buffer 504. For example, the to-be-written data obtained by the memory controller in the foregoing process refers to the read results LP0_r, MP0_r, UP0_r, and XP0_r corresponding to the original to-be-written data LP0, MP0, UP0, and XP0 that are read by the memory controller from the page buffer 504. By sending the original to-be-written data to the page buffer, and then reading the read result corresponding to the original to-be-written data from the page buffer as the to-be-written data, it is intended to simulate the process of writing the original to-be-written data to the memory cell of the memory device and reading the read result corresponding to the original to-be-written data from the memory cell of the memory device as the coarse programming data.

In some examples, the memory controller is configured to: obtain the to-be-written data from the memory device before encoding the to-be-written data. For example, taking QLC as an example, the memory controller is configured to: obtain data (LP0_r, MP0_r, UP0_r, and XP0_r) to be written into four pages from the page buffer of the memory device, and perform the logical operation on the data (LP0_r, MP0_r, UP0_r, and XP0_r) to be written into the four pages to obtain three encoded data (the first encoded data Parity1, the second encoded data Parity2, and the third encoded data Parity3).

The complete flow of simulating writing data into the memory cell of the memory device and reading data by sending the original to-be-written data to the page buffer and reading the original to-be-written data, may simulate whether errors or data damage occurs in the data writing and reading processes, and the accuracy is higher when the to-be-written data obtained by the memory controller represents the reading result corresponding to the data actually written into the memory device in the first programming operation process. In addition, the speed of writing the data into the page buffer and reading the data is high, the power consumption is low, and it would not occupy excessive resources for power loss protection.

In some examples, the memory controller comprises an error correction encoding module and an error correction decoding module; and the memory controller is configured to: control to disable the error correction encoding module before writing the encoded data into the memory device; and control to disable the error correction decoding module after obtaining the encoded data from the memory device.

In some examples, as shown in FIG. 7, the memory controller 106 comprises an error correction encoding module 1065 and an error correction decoding module 1066, where the error correction encoding module 1065 is configured to encode the to-be-stored data to obtain check data, and the error correction decoding module 1066 is configured to decode the check data to detect and correct possible error data in a data transmission process.

For example, the memory controller 106 is configured to: control to disable error correction encoding module 1065 before writing the encoded data into the memory device 104. Since the algorithm employed by the error correction encoding module (for example, the ECC error correction algorithm) is different from the principle of the logic operation employed to perform the logical operation on the to-be-written data to obtain the encoded data, encoding the encoded data generated by the logical operation again may cause the data structure originally dedicated to obtaining the encoded data of the error recovery data to be damaged, which may cause not be able to successfully obtain the error recovery data required to re-perform the programming operation when power-on after the power-down. In order to ensure the accuracy of the encoded data in obtaining the error recovery data required to re-perform the programming operation when power-on after the power-down, it is not necessary to perform error correction encoding on the encoded data here.

In some examples, the memory controller 106 is configured to: control to disable error correction decoding module 1066 after obtaining the encoded data from the memory device 104. Similarly, in order to ensure the accuracy of the encoded data in obtaining the error recovery data required to re-perform the programming operation when power-on after the power-down, it is not necessary to perform error correction decoding on the encoded data here.

In some examples, the memory device comprises a plurality of memory cells each having N memory bits, wherein N is an integer greater than 2; as shown in FIG. 7, the memory device 104 comprises a first memory area 1041 and a second memory area 1042; the memory cell in the first memory area 1041 reads or writes one bit of data in a first mode, and the memory cell in the second memory area 1042 reads or writes N bits of data in a second mode; and the memory controller 106 is configured to: write the encoded data into the memory device 104 in the first mode; and control the memory device 104 to read the encoded data in the first mode before obtaining the encoded data from the memory device 104.

In some examples, the first mode may be understood as Single Level Read (SLR) mode or Single Level Write (SLW) mode. The second mode may be understood as a Multi-Level Read (MLR) mode or a Multi-Level Write (MLW) mode.

For example, in a Single Level Write mode, a write operation refers to writing one bit of memory data to one page. In a Single Level Read mode, a read operation reads one bit of memory data in one page. For example, when reading the middle page MP shown in FIG. 8, whether the one bit of memory data corresponding to the middle page MP is 0 or 1 is read by using the first level read voltage between P6 and P7.

In some implementations, the memory controller 106 is configured to: write the encoded data into the memory device 104 in a Single Level Write mode.

In some implementations, the memory controller 106 is configured to: control the memory device 104 to read the encoded data in a Single Level Read mode before obtaining the encoded data from the memory device 104.

According to the examples of the present disclosure, the speed of the first mode is fast and the operation is simple, and writing the encoded data into the memory device in the first mode when power-down can safely store the encoded data in the memory device in time, thus reducing the risk of data loss. When power-on after power-down, before obtaining the encoded data from the memory device, controlling the memory device to read the encoded data in the first mode helps to increase the speed of obtaining the error recovery data required to re-perform the programming operation, and the overall time of the programming operation is reduced.

In addition, by dividing the memory region of the memory device into a first memory area configured to store encoded data with high reliability requirements and a second memory area configured to store regular data with high capacity demand, and using different modes (the first mode and the second mode) for write operation and read operation in the first memory area and the second memory area, the memory space can be fully utilized and the performance of the memory device can be effectively optimized.

In some examples, the encoded data and the written data are obtained from the memory device before the encoded data and the written data are decoded.

In some examples, the memory controller is configured to: obtain a target reference voltage corresponding to the first programming operation before obtaining the written data; and control the memory device to perform a read operation on the written data with the target reference voltage.

It should be noted that, the target reference voltage herein is the optimal read voltage found by the method in the examples of the present disclosure, and the target reference voltage may be employed to accurately perform the read operation on the written data, and the accuracy of the read result (the written data) is improved. The manner in which the target reference voltage is obtained will be further described below.

In some examples, the memory controller is configured to: perform an OR logical operation or an AND logical operation on the data to be written into every two pages of N pages to obtain the encoded data; and perform an OR logical operation and an AND logical operation on the encoded data and the written data to obtain the at least a portion of error recovery data.

Hereinafter, the QLC will be taken as an example to describe in detail the operation flow of obtaining the encoded data and obtaining at least a portion of the error recovery according to the encoded data. In an example:
Operation a1: when power-down occurs during the first programming operation, obtaining the original to-be-written data LP0, MP0, UP0 and XP0 from the buffer, where LP0 represents the original to-be-written data corresponding to the LP, MP0 represents the original to-be-written data corresponding to the MP, UP0 represents the original to-be-written data corresponding to the UP, and XP0 represents the original to-be-written data corresponding to the XP.
Operation a2: sending the original to-be-written data LP0, MP0, UP0, and XP0 to a page buffer of the memory device.
Operation a3: reading the original to-be-written data LP0, MP0, UP0, and XP0 from the page buffer of the memory device to obtain read results LP0_r, MP0_r, UP0_r, and XP0_r corresponding to the original to-be-written data LP0, MP0, UP0, and XP0, where LP0_r, MP0_r, UP0_r, and XP0_r are also referred to as to-be-written data in the present disclosure. LP0_r represents to-be-written data corresponding to the LP, MP_r represents to-be-written data corresponding to the MP, UP_r represents to-be-written data corresponding to the UP, and XP_r represents to-be-written data corresponding to the XP.
Operation a4: performing an AND logical operation on the to-be-written data LP0_r, MP0_r, UP0_r, and XP0_r in every two pages to obtain encoded data. In an example, the AND logical operation is performed on the to-be-written data LP0_r and MP0_r to obtain first encoded data Parity 1, the AND logical operation is performed on the to-be-written data MP0_r and LP0_r to obtain second encoded data Parity 2, and the AND logical operation is performed on the to-be-written data LP0_r and XP0_r to obtain third encoded data Parity 3.
Operation a5: writing the encoded data (the first encoded data Parity1, the second encoded data Parity2, and the third encoded data Parity3) into the memory device in the first mode. It should be noted that, the error correction encoding module is controlled to disable before writing the encoded data into the memory device.
Operation a6: obtaining the encoded data and the written data from the memory device when power-on after power-down.

In an example, on the one hand, the memory device is controlled to read the encoded data (the first encoded data Parity 1, the second encoded data Parity2, and the third encoded data Parity3) in the first mode to obtain the read result Parity 1_r, the second encoded data Parity2_r, and the third encoded data Parity3_r corresponding to the first encoded data Parity1, the second encoded data Parity2, and the third encoded data Parity3 respectively. It should be noted that, the error correction decoding module is controlled to disable after obtaining the encoded data from the memory device.

On the other hand, a target reference voltage corresponding to the first programming operation is obtained; and the memory device is controlled to perform a read operation on the written data with the target reference voltage to obtain read results LP_raw, MP_raw, UP_raw, and XP_raw corresponding to the written data, where LP_raw represents a read result corresponding to the written data corresponding to the LP, MP_raw represents a read result corresponding to the written data corresponding to the MP, UP_raw represents a read result corresponding to the written data corresponding to the UP, and XP_raw represents a read result corresponding to the written data corresponding to the XP.
Operation a7: decode the obtained encoded data and the written data corresponding to the first programming operation to obtain at least the portion of error recovery data corresponding to the written data.

For example, an OR logical operation is performed on the obtained read results Parity1_r and LP_raw and MP_raw corresponding to the first encoded data Parity 1 respectively to complete the first operation of recovery (the detected 0 is flipped to 1), and to obtain first error recovery data LP1 and second error recovery data MP1 respectively.

For example, an OR logical operation is performed on the obtained read results Parity2_r and MP1 and UP raw corresponding to the second encoded data Parity2 respectively to complete the second operation of recovery (the detected 0 is flipped to 1), and to obtain third error recovery data MP2 and fourth error recovery data UP1 respectively.

For example, an OR logical operation is performed on the obtained read results Parity3_r and UP1 and XP raw corresponding to the third encoded data Parity3 respectively to complete the third operation of recovery (the detected 0 is flipped to 1), and to obtain fifth error recovery data UP2 and sixth error recovery data XP1 respectively.

For example, after a NOT logical operation is performed on the obtained read result Parity2_r corresponding to the second encoded data Parity2, an AND logical operation is performed on it and the fifth error recovery data UP2 to obtain first intermediate data, and after a NOT logical operation is performed on the first intermediate data, an AND logical operation is performed on it and the third error recovery data MP2 to obtain seventh error recovery data MP3.

For example, after a NOT logical operation is performed on the obtained read result Parity2_r corresponding to the second encoded data Parity2, an AND logical operation is performed on it and the seventh error recovery data MP3 to obtain the second intermediate data, and after a NOT logical operation is performed on the second intermediate data, an AND logical operation is performed on it and the fifth error recovery data UP2 to obtain eighth error recovery data UP3.

For example, after a NOT logical operation is performed on the obtained read result Parity 1_r corresponding to the first encoded data Parity 1, an AND logical operation is performed on it and the seventh error recovery data MP3 to obtain the third intermediate data, and after a NOT logical operation is performed on the third intermediate data, an AND logical operation is performed on it and the first error recovery data LP1 to obtain ninth error recovery data LP2.

For example, after a NOT logical operation is performed on the obtained read result Parity3_r corresponding to the third encoded data Parity3, an AND logical operation is performed on it and the eighth error recovery data UP3 to obtain the fourth intermediate data, and after a NOT logical operation is performed on the fourth intermediate data, an AND logical operation is performed on it and the sixth error recovery data XP1 to obtain tenth error recovery data XP2.

So far, the decoding process of the obtained encoded data and the written data corresponding to the first programming operation ends, where the ninth error recovery data LP2 is the error recovery data of the written data corresponding to the LP of the first programming operation, the seventh error recovery data MP3 is the error recovery data of the written data corresponding to the MP of the first programming operation, the eighth error recovery data UP3 is the error recovery data of the written data corresponding to the UP of the first programming operation, and the tenth error recovery data XP2 is the error recovery data of the written data corresponding to the XP of the first programming operation.

It should be noted that there is correspondence between the manner of the logical operation employed to obtain the encoded data through encoding process and the manner of the logical operation employed to perform decoding on the obtained encoded data and the written data, so that data can be recovered by decoding the obtained encoded data when power-on after power-down.

In some examples, the memory controller is further configured to: control the memory device to re-perform a programming operation with the error recovery data.

In some examples, by decoding the encoded data and the written data corresponding to the first programming operation to obtain at least a portion of the error recovery data, it can ensure the data integrity when the first programming operation process suffers from the power-down, and re-performing the programming operation with the error recovery data can reduce the risk of failure of the overall programming operation and improve the reliability of the programming operation.

It should be noted that the executing body of the detailed implementation process of each operation in operations a1 to a7 may be a memory controller, and in an example, the executing body of the detailed implementation process of each operation in operations a1 to a7 may be a processor in a memory controller.

Next, a manner in which the target reference voltage is obtained is further described.

In some examples, the memory controller is configured to: obtain M flip results at M reference read voltages corresponding to at least one codeword formed by a preset number of memory cells, wherein each of the flip results indicates the number of flipped bits of the at least one codeword in two read results at a first and second read voltage, a difference between the first and second read voltage is less than a preset voltage, and M is an integer greater than or equal to 2; obtain a predicted valley voltage according to the M flip results and the M reference read voltages in combination with a preset function model, wherein the preset function model represents a relationship between the flip results and the reference read voltages, and the M flip results are all within a preset interval; and determine the target reference voltage based on the predicted valley voltage.

It should be noted that the predicted reference voltage herein may be directly used as the target reference voltage to perform a read operation on the to-be-read data as needed, or further processing is performed to obtain the target reference voltage. The manner in which the predicted reference voltage is obtained is further described below.

Next, the process of obtaining the target reference voltage according to the preset function model and the first parameter thereof is described in detail.

First, the meaning of the flip result and the manner in which the flip result is obtained are described.

Here, the flip result indicates the number of flipped bits of the at least one codeword in two read results on which the read operation is performed at the first and second read voltage.

In some examples, the preset number of memory cells form one codeword (CW). One page comprises one or more codewords. For example, a number of memory cells included in one codeword is the same as a number of memory cells included in one error correction encoding or error correction decoding when performing error correction encoding or error correction decoding. In some examples, a number of memory cells included in one codeword may be less than or equal to a number of memory cells coupled to one page, for example, a number of memory cells included in one codeword is ¼ of a number of memory cells coupled to one page.

In general, different memory systems may select codewords of different sizes to meet their performance, reliability, and memory requirements. Memory cells (e.g., MLC, TLC, or QLC) in different types of memory devices may store different numbers of bits. It may be understood that the codeword may include a plurality of memory cells, and the number of memory cells included in the codeword may be adjusted according to actual conditions. Here, both the first and second read voltage refer to a general concept, and a difference between the first and second read voltage is less than a preset voltage.

In some examples, the second read voltage is greater than the first read voltage, the difference between the first and second read voltage ranges from 5 mV to 20 mV, and for example, the difference between the first and second read voltage may be 5 mV, 10 mV, 15 mV, 20 mV. In some other examples, the second read voltage is less than the first read voltage, the difference between the first and second read voltage ranges from −5 mV to −20 mV, and for example, the difference between the first and second read voltage may be −5 mV, −10 mV, −15 mV, and −20 mV.

In some examples, the memory device is configured to: read the stored data of the at least one codeword at the first read voltage to obtain a first result; read the stored data of the at least one codeword at the second read voltage to obtain a second result; perform a logical operation on the first and second result to obtain a third result; and count the number of bits in the third result representing that bits of the second result are flipped relative to the first result to obtain the flip result.

In some examples, the memory device comprises: a first latch configured to store the first result; a second latch configured to store the second result; and a third latch configured to store the third result.

Here, the first and second read voltage are interrelated, for example, the second read voltage is obtained by making a third adjustment based on the first read voltage. Based on this, the voltage difference between the first and second read voltage is the third step size. In some examples, the third step size ranges from 5 mV to 20 mV, for example, the third step size may be 5 mV, 10 mV, 15 mV, 20 mV. The preset voltage is related to the third step size and may be a voltage slightly larger than the third step size. In some examples, the preset voltage ranges from 6 mV to 21 mV, for example, the preset voltage may be 6 mV, 11 mV, 16 mV, 21 mV. In some other examples, the preset voltage ranges from −6 mV to −21 mV, for example, the preset voltage may be −6 mV, −10 mV, −16 mV, and −21 mV.

As described above, both the first and second read voltage refer to a general concept, both the target read voltage and the read voltage obtained after the first adjustment and the second adjustment made on the target read voltage may be referred to as the first read voltage, and the read voltage obtained after the third adjustment made on the first read voltage may be referred to as the second read voltage. For example, the first read voltage is a general concept, it may be understood as the target read voltage or the target adjusted read voltage (e.g., the voltage obtained after the target read voltage is adjusted by using the target step size, where the target step size may range from 20 mV to 40 mV, for example, the first step size of the first adjustment may be 20 mV, 30 mV, 40 mV, and the target step size may also range from 50 mV to 150 mV, for example, the second step size of the second adjustment may be 50 mV, 60 mV, 70 mV, 80 mV, 100 mV, 120 mV, or 150 mV).

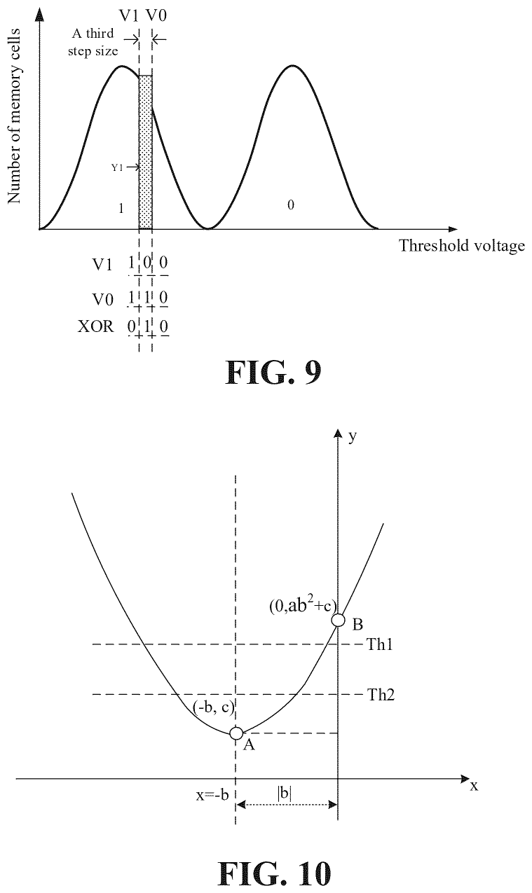

In the examples of the present disclosure, a flip result corresponding to a certain voltage (for example, the first read voltage V0 shown in FIG. 9) may be understood as: performing a third adjustment on the certain voltage, for example, the certain voltage and a certain voltage after the third adjustment (for example, the second read voltage V1 shown in FIG. 9) have a first voltage difference ΔV1, and a number of bits that are flipped between both read results of the at least one codeword at the certain voltage and the certain voltage after the third adjustment may be employed as a flip result corresponding to the voltage.

In some examples, before obtaining the flip result of the at least one codeword corresponding to the target read voltage, the read mode of the memory device is set to a first mode.

In some examples, the stored data of the at least one codeword is read at the first read voltage to obtain a first result; the first result is stored in the first latch of the memory device. For example, as shown in FIG. 9, the stored data of the at least one codeword is read at the first read voltage V0 to obtain a first result. For example, to obtain a first result, the memory cell with a threshold voltage less than the target read voltage V0 is marked as bit 1, and the memory cell with a threshold voltage greater than the target read voltage V0 is marked as bit 0, then the first result is stored in the first latch of the memory device.

Next, a third adjustment is performed on the first read voltage to obtain a second read voltage, and the stored data of the at least one codeword is read at the second read voltage to obtain a second result; and the second result is stored in the second latch of the memory device. For example, as shown in FIG. 9, a third adjustment is performed on the first read voltage V0, and the stored data of the at least one codeword is read at the second read voltage V1 after the adjustment to obtain a third result. For example, to obtain a second result, the memory cell with the threshold voltage less than the second read voltage V1 is marked as bit 1, and the memory cell with the threshold voltage greater than the second read voltage V1 is marked as bit 0, then the second result is stored in the second latch of the memory device.

Next, a logical operation is performed on the first result and the second result to obtain a third result; and the third result is stored in the third latch of the memory device. For example, as shown in FIG. 9, an XOR operation is performed on the first result and the second result to obtain a third result; and the third result is stored in the third latch of the memory device.

It should be noted that, the XOR operation is one of basic logic operations. In binary, if the two binary numbers of the same location are the same, the result is “0”, and if the two binary numbers of the same location are different, the result is “1” (for example, 0 when the same, and 1 when different).

Next, the number of bits in the third result representing the second result is flipped relative to the first result is counted, so as to obtain the flip result. For example, as shown in FIG. 9, a part of the third result with a bit of 1 represents a number of memory cells with different threshold voltages between the first read voltage V0 and the second read voltage V1. For example, the part of the third result with a bit of 1 represents a number of bits that is flipped in both read results of the at least one codeword at the first read voltage V0 and the second read voltage V1, and the number is denoted as a first result Y1 corresponding to the first read voltage V0.

In some examples, the preset model is a quadratic function model, and the preset interval represents a range between a first threshold and a second threshold of a curve where the quadratic function model is located; the first threshold is greater than the second threshold.

In some examples, the memory controller is configured to: obtain a corresponding first result of the at least one codeword at a target read voltage; and according to the corresponding first result of the at least one codeword at the target read voltage being within the preset interval, take the target read voltage as a reference read voltage, and take the corresponding flip result within the preset interval as a flip result at the reference read voltage.

In some examples, the memory controller is configured to: obtain a prediction parameter of the quadratic function model according to the M flip results and the M reference read voltages in combination with the quadratic function model; the prediction parameter is a corresponding reference read voltage when a flip result in a curve where the quadratic function model is located is minimum; obtain a predicted reference voltage according to the prediction parameter; and determine a target reference voltage based on the predicted reference voltage.

In some implementations, the equation in the fitted preset function model comprises the related parameter, and when the predicted reference voltage is obtained, the value of the related parameter may be obtained according to the M flip results and the M reference read voltages and the equation. And the corresponding reference read voltage is then obtained when the flip result in the curve where the preset function model is located is minimum. And the corresponding reference read voltage may be the predicted reference voltage when the flip result in the curve where the preset function model is located is minimum.

In some examples, the preset function model comprises a quadratic function model, and the quadratic function model comprises the following equation:

$$y = {a ( x + b )}^{2} + c$$

where y is a flip result, x is a reference read voltage, b is to represent a prediction parameter, a is a first parameter, and c is a second parameter.

As shown in FIG. 10, it can be learned from the equation included in the quadratic function model that, the extreme value of the curve where the quadratic function model is located is at x=−b where the axis of symmetry is located, e.g., a location where the derivative of the curve is 0. For example, when the first parameter is greater than 0, a corresponding y value (a flip result) at x=−b is a minimum value of a curve where the quadratic function model is located, and a coordinate of the extreme point (point A shown in FIG. 10) is (−b, c).

In some implementations, the value of the prediction parameter is the opposite number of b, for example, the prediction parameter represents the abscissa corresponding to the minimum value of the curve where the quadratic function model is located.

As shown in FIG. 10, the offset value of the axis of symmetry (x=−b) of the curve (where the quadratic function model is located) relative to the y axis (x=0) is −b, for example, the distance between the axis of symmetry of the curve (where the quadratic function model is located) and the y axis is the absolute value |b| of b.

Here, x=0 may be understood as the location of the default read voltage, the term “the flip result corresponding to the default read voltage” in the present disclosure may be referred to as “default flip result”, and the coordinate corresponding to the default flip result (point B shown in FIG. 10) is (0, ab²+c). The default read voltage may be a read voltage when the threshold voltage of the memory cell is not offset, for example, a corresponding read voltage when being written at the beginning, and the corresponding offset value is 0. It can be understood that when the offset value of the target read voltage relative to the default read voltage (x=0) is −b, the flip result corresponding to the target read voltage is the minimum value. It may be understood that by using the corresponding target read voltage (here equivalent to the prediction parameter) as the predicted reference voltage when the flip result is the minimum value, and determining the target reference voltage based on the predicted reference voltage, the error rate of the read result is low, and the reliability is high.

It should be noted that when using the corresponding target read voltage (here equivalent to the prediction parameter) as the predicted reference voltage when the flip result is the minimum value, for example, using −b as the predicted reference voltage, it represents the offset value of the predicted reference voltage relative to the default read voltage is −b, and does not represent that the predicted reference voltage is negative. When-b is greater than 0, it indicates that the predicted reference voltage is |b| shifted to the right compared to the default read voltage, and when-b is less than 0, it indicates that the predicted reference voltage is |b| shifted to the left compared to the default read voltage. For example, the relationship between the actual voltage of the predicted reference voltage (denoted as Vpre) and the actual voltage of the default read voltage (denoted as Vdefault) is as follows:

$$V pre = V default + ( - b )$$

Similarly, after the target reference voltage is determined based on the predicted reference voltage, applying the target reference voltage to perform the read operation on the at least one codeword refers to applying the actual voltage of the target reference voltage to perform the read operation on the at least one codeword. It should be noted that there exists and there is only one set of prediction parameters, it is directly as the prediction reference voltage. However, when there are multiple sets of prediction parameters, it is required to jointly determine the prediction reference voltage according to the multiple sets of prediction parameters.

In some examples, as shown in FIG. 10, the preset interval represents a range between the first threshold and the second threshold of the curve where the quadratic function model is located; the first threshold (Th1) is greater than the second threshold (Th2).

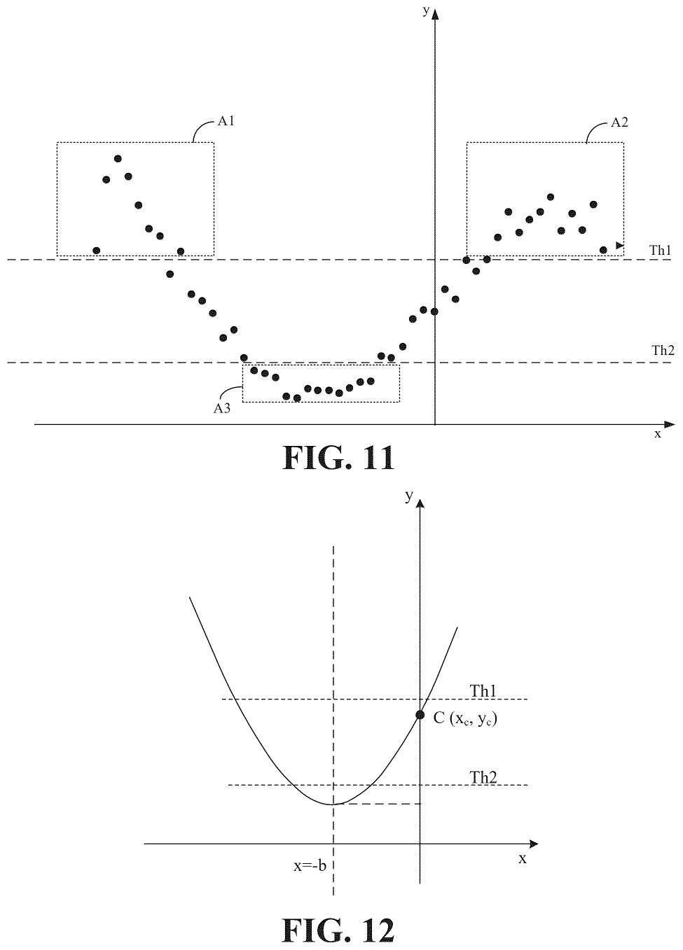

FIG. 11 is a schematic diagram of determining a preset interval according to an example of the present disclosure. In some examples, the plurality of solid dots shown in FIG. 11 represent a large amount of data (the plurality of target read voltages and the plurality of flip results corresponding to the plurality of target read voltages) collected through a large number of experiments before the memory device leaves the factory, and when the preset function model is fitted based on the data shown in FIG. 11, the data selection is directly related to the accuracy of the preset function model obtained by fitting. For example, when the flip result of the selected data is too high (for example, the solid dots in the dotted box region A1 or the dotted box region A2 shown in FIG. 11), the preset function model obtained by fitting will be different from the distribution curve of the actual threshold voltage, and for example, the preset function model obtained by fitting the selected solid dots in the dotted box region A1 or the dotted box region A2 is the quadratic function model with a downward opening, which is not consistent with the distribution curve of the actual threshold voltage (quadratic function model with an upward opening). When the flip result of the selected data is too low (for example, the solid dots in the dotted box region A3 shown in FIG. 11), the error of the preset function model obtained by fitting is too large, resulting in that the location deviation between the target reference voltage obtained according to the preset function model and the actual read voltage is too large.

In some examples, the range of the preset interval is from 50 to 200.

It should be noted that the range of the preset interval provided in this example of the present disclosure is merely an example, the range of the preset interval is related to a characteristic of the memory device, and the protection scope of the present disclosure should not be limited.

In some examples, the memory controller is configured to: obtain a corresponding flip result of the at least one codeword at a target read voltage; and take the target read voltage as a reference read voltage according to the corresponding flip result of the at least one codeword at the target read voltage being within the preset interval; and re-obtain at least one new target read voltage according to the corresponding flip result of the at least one codeword at the target read voltage being outside the preset interval, and obtain a corresponding flip result at the at least one new target read voltage, until the corresponding flip result at the latest target read voltage is within the preset interval.

Here, the first parameter and the second parameter may be obtained when fitting the preset function model and stored in the memory device.

For example, the preset function model comprises a quadratic function model, and the quadratic function model comprises the following equation (1):

$$y = {a ( x + b )}^{2} + c$$

The first parameter and the second parameter in the equation may be optimized with, but not limited to, least square method, gradient descent method, Bayesian optimization, Newton method, and quasi-Newton method, and the optimal first and second parameter may be stored in the memory device. The least square method is a parameter estimation method, and parameters are estimated by minimizing a sum of squares of residuals between actual collected data and predicted values of a quadratic function model. The gradient descent method is to apply a parameter of the quadratic function model as an optimization target, employ a gradient descent method to find a parameter value that minimizes a fitting error of the quadratic function model, calculate a gradient of a loss function with respect to the first parameter and the second parameter, and then update values of the first parameter and the second parameter along the reverse direction of the gradient until convergence is reached.

In some examples, as shown in FIG. 12, the memory controller is configured to: obtain a corresponding flip result of the at least one codeword at the target read voltage, for example, obtain the point C(x_{c},y_{c}) shown in FIG. 12; the flip result corresponding to the point C(y_{c}) is within the preset interval, and applies the target read voltage (x_{c}) corresponding to the point C as a reference read voltage.

It should be noted that the default flip result being the point C is taken as an example in FIG. 12, and should not limit the protection scope of the present disclosure. In addition, the point C is a point corresponding to the flip result obtained at the default read voltage in the manner of obtaining the flip result in the foregoing example, so the point C is an actual value, may or may not be located on the curve where the quadratic function model is located.

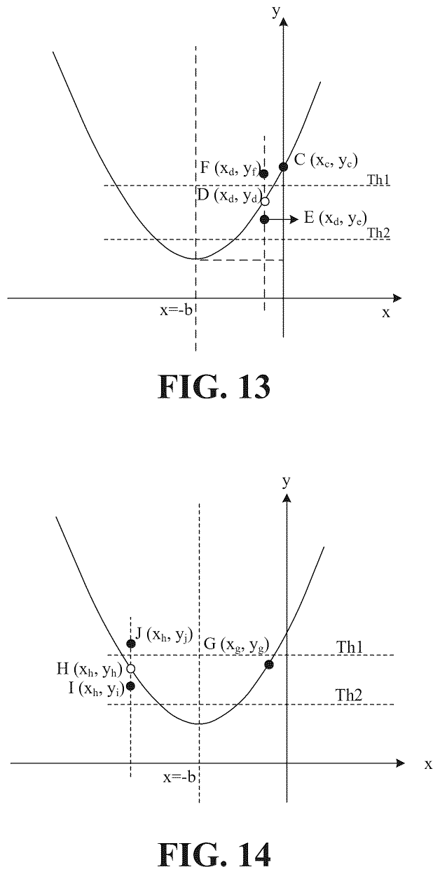

In some examples, as shown in FIG. 13, the memory controller is configured to: re-obtain at least one new target read voltage according to a flip result (y_{c}) corresponding to the point C(x_{c}, y_{c}) being outside a preset interval, and obtain a corresponding flip result at the at least one new target read voltage until the corresponding flip result at the latest target read voltage is within the preset interval.

It can be understood that only when the corresponding flip result at the target read voltage is within the preset interval, the target read voltage can be taken as the reference read voltage to obtain the predicted reference voltage. In this way, accuracy and reliability of obtaining the predicted reference voltage based on the plurality of reference read voltages and the plurality of flip results can be enhanced.

In some examples, at least two of the M reference read voltages are at both sides of an axis of symmetry of a curve where the quadratic function model is located; and the memory controller is configured to: obtain a reference read voltage at a first side of the both sides of an axis of symmetry of a curve where the quadratic function model is located when obtaining the reference read voltage; and determine a reference read voltage at a second side of the both sides of the axis of symmetry according to the reference read voltage at the first side.

In some examples, the first parameter and the second parameter may be derived when fitting the preset function model and stored in the memory device. An initial b value may be obtained according to a coordinate of the point C in FIG. 12 or FIG. 13, the equation of the quadratic function model, the first parameter, and the second parameter. The axis of symmetry x=−b of the curve where the quadratic function model is located can be obtained according to the initial b value.

It should be noted that the first side refers to one side of the axis of symmetry (x=−b as shown in FIG. 13 and FIG. 14) of the curve where the quadratic function model is located, and the second side refers to the other side of the axis of symmetry of the curve where the quadratic function model is located. When the first side is the right side of the axis of symmetry, the second side is the left side of the axis of symmetry. When the first side is the left side of the axis of symmetry, the second side is the right side of the axis of symmetry.

For example, the target read voltage (x_{c}) corresponding to the point C in FIG. 12 is the reference read voltage at the first side of the both sides of the axis of symmetry of the curve where the quadratic function model is located.

Next, the process of obtaining the reference read voltage at the first side of the both sides of the axis of symmetry of the curve where the quadratic function model is located and obtaining the reference read voltage at the second side of the both sides of the axis of symmetry will be described in detail.

In some examples, the method for re-obtaining the at least one new target read voltage according to the corresponding flip result of the at least one codeword at the target read voltage is outside the preset interval comprises, but is not limited to, after the target read voltage is adjusted by the target step size, taking the resulting read voltage as the new target read voltage. For example, as shown in FIG. 13, the read voltage (x_{d}), obtained after the target read voltage (x_{c}) is adjusted by the target step size, is taken as the new target read voltage. The corresponding flip result (yₑ) of the at least one codeword at the new target read voltage is obtained, for example, the point E (x_{d}, yₑ) shown in FIG. 13 is obtained. In this case the point E is an actual value. When the flip result (yₑ) corresponding to the point E is within the preset interval, the new target read voltage (x_{d}) corresponding to the point E is taken as a reference read voltage. And the range of the target step size may be set to 20 mV to 40 mV, for example, the step size of the first adjustment may be 20 mV, 30 mV, 40 mV. The range of the target step size may also be set to 50 mV to 150 mV, for example, the step size of the second adjustment may be 50 mV, 60 mV, 70 mV, 80 mV, 100 mV, 120 mV, or 150 mV.

In some implementations, the memory controller is configured to: according to the corresponding flip result of the at least one codeword at the target read voltage being outside the preset interval, obtain a fitted read voltage at the first side corresponding to the target flip result based on the target read voltage, the corresponding flip result at the target read voltage, the target flip result, and the third mapping function, wherein the third mapping function being obtained according to the quadratic function model, the first parameter, and the second parameter, the target flip result being within a reference preset interval, and the preset interval being within a range of the reference preset interval.

For example, as shown in FIG. 13, the memory controller is configured to: according to the flip result (y_{c}) corresponding to the point C(x_{c},yₑ) being outside the preset interval, obtain the fitted read voltage (x_{d}) at the first side corresponding to the target flip result (y_{d}) based on the target read voltage (x_{c}), the corresponding flip result (yₑ) at the target read voltage, the target flip result (y_{d}), and the third mapping function, for example, obtain the point D (x_{d},y_{d}) according to the coordinates of the point C, the target flip result (y_{d}), and the third mapping function, wherein the third mapping function comprises the following equation (2):

$$x 2 = x 1 - \sqrt{\frac{y 1 - c}{a}} + \sqrt{\frac{y 2 - c}{a}}$$

Where x1 and y1 represent the abscissa and ordinate of the obtained actual point respectively, y2 represents the target flip result which is a random value within the reference preset interval, and x2 represents the fitted read voltage. The third mapping function is intended to obtain a fitted read voltage (for example, x_{d} shown in FIG. 13) according to a value within the reference preset interval in combination with the obtained actual point (for example, the point C). The preset interval is within a range of the reference preset interval. Optionally, the reference preset interval ranges from 30 to 220.

The coordinates of the point C, the target flip result (y_{d}), the first parameter and the second parameter are substituted into the equation (2) of the first mapping function to obtain the point D (x_{d},y_{d}).

It should be noted that FIG. 13 and the third mapping function are described by taking the first side as the right side of the axis of symmetry and the point C at the first side.

In this case, the point D (x_{d},y_{d}) is a fitted point, the abscissa x_{d} corresponding to the point D is the fitted read voltage at the first side, and the memory controller is configured to: take the fitted read voltage as a new target read voltage, obtain a corresponding flip result (yₑ) of the at least one codeword at the fitted read voltage (x_{d}) at the first side in the manner of obtaining the flip result in the foregoing example, for example, obtain the point E (x_{d},yₑ), and the point E is the actual point; and take the fitted read voltage (x_{d}) at the first side as a reference read voltage at the first side according to the corresponding flip result (the ordinate yₑ corresponding to the point E) at the fitted read voltage at the first side being within the preset interval.

In some examples, take the fitted read voltage (the abscissa x_{d} corresponding to the point D) at the first side as a new target read voltage, and obtain a corresponding flip result (y_{f}) of the at least one codeword at the fitted read voltage (x_{d}) at the first side in the manner of obtaining the flip result in the foregoing example, for example, obtain the point F (x_{d},y_{f}). The memory controller is further configured to: according to the corresponding flip result (the ordinate yr of the point F) at the fitted read voltage at the first side being outside the preset interval, obtain a next fitted read voltage at the first side corresponding to the target flip result based on a last fitted read voltage at the first side, a last corresponding flip result at the last fitted read voltage at the first side, the target flip result, and the third mapping function, until the latest corresponding flip result at the fitted read voltage at the first side is within the preset interval, and take the latest fitted read voltage at the first side as a reference read voltage at the first side. It may be understood that it is obtaining the next fitted read voltage at the first side corresponding to the target flip result based on the last known actual point F (x_{d},y_{f}), the target flip result (a random value different from y_{d} in the reference preset interval), and the third mapping function e.g., equation (2), until the latest corresponding flip result at the fitted read voltage at the first side is within the preset interval, and then taking the latest fitted read voltage at the first side as a reference read voltage at the first side.

In some examples, the memory controller is configured to: adjust the value of the first parameter according to the number of times that the latest corresponding flip result at the fitted read voltage at the first side is outside the preset interval is greater than or equal to the preset number of times, and adjust the third mapping function accordingly; obtain a next adjusted fitted read voltage at the first side corresponding to the target flip result based on the last fitted read voltage at the first side, the last corresponding flip result at the fitted read voltage at the first side, the target flip result, and the adjusted third mapping function, until the latest corresponding flip result at the adjusted fitted read voltage at the first side is within the preset interval.

Here, the preset number of times represents the upper limit of the number of trials of using the preset function model, and if, after the preset number of times of trials, the corresponding flip results at the fitted read voltage at the first side obtained by the preset function model are all outside the preset interval, it means that the selected preset function model may not meet the actual requirement, and a further parameter adjustment is required. The preset number of times may be adjusted according to actual conditions, in some examples, the preset number of times are 3-7 times, for example, the preset number of times may be 3, 5, or 7.

In some examples, when the number of times, that the corresponding flip result at the fitted read voltage at the first side obtained by applying the method in the foregoing example is outside the preset interval, is greater than or equal to the preset number of times, it indicates that a plurality of actual points have been obtained at this time. The value of the adjusted first parameter may be obtained according to the obtained plurality of actual points in combination with the equation (1) and the second parameter (a constant) of the quadratic function model. It can be understood that adjusting the first parameter of the quadratic function model in combination with the actual point during actual use can improve the accuracy and reliability of the quadratic function model, and can make the adjusted first parameter infinitely close to the first parameter corresponding to the actual read voltage distribution curve. Therefore, the actual situation can be better reflected, the change of the actual use scene can be flexibly applied, and the practicability of the quadratic function model is improved.

For example, the preset number of times is 3, and the number of times that the corresponding flip result at the fitted read voltage at the first side obtained by the method in the foregoing example is outside the preset interval is equal to 3, for example, at least 3 actual points are obtained, and coordinates of the 3 actual points are denoted as (x3, y3) and (x4, y4), and (x5, y5) respectively. According to any 2 actual points in the obtained 3 actual points, such as (x3, y3) and (x4, y4), in combination with the equation (1) of the quadratic function model, a formula (1) to obtain b may be as follows:

$$b = \frac{x 4 - x 3}{1 + \sqrt{\frac{y 3 - c}{y 4 - c}}} - x 4$$

Based on the formula (1) to obtain b, according to the equation of the quadratic function model and the second parameter being a constant, the formula (2) of the first parameter may be as follows:

$$a = \frac{y 3 - c}{{( x 3 + 〚 b ) 〛}^{2}}$$

It may be understood that the first parameter obtained herein may be taken as the first parameter in the (N+1)th updated parameter table.

For example, according to the obtained 3 actual points in combination with the equation (1) of the quadratic function model, the formula (3) to obtain b may be as follows:

$$b = \frac{( y 4 - y 3 ) \times ( x {5}^{2} - x {4}^{2} ) - ( y 5 - y 4 ) \times ( x {4}^{2} - x {3}^{2} )}{2 \times ( ( y 5 - y 4 ) \times ( x 4 - x 3 ) - ( y 4 - y 3 ) \times ( x 5 - x 4 ) )}$$

Based on the formula (3) to obtain b, according to the equation (1) of the quadratic function model and the second parameter being constant, the formula (4) to obtain the first parameter may be as follows:

$$a = \frac{y 4 - y 3}{( x {4}^{2} - x {3}^{2} ) + 2 \times ( x 4 - x 3 ) \times b}$$

In this way, the adjusted value of the first parameter may be obtained, and the adjusted value of the first parameter may be substituted into the equation (2) of the third mapping function to correspondingly adjust the third mapping function.

In some examples, the memory controller is configured to: obtain a fitted read voltage at the second side corresponding to the target flip result based on a reference read voltage at the first side, a corresponding flip result at a reference read voltage at the first side, a target flip result, and a fourth mapping function, wherein the fourth mapping function is obtained according to the quadratic function model, the first parameter/adjusted first parameter, and the second parameter; obtain a corresponding flip result of the at least one codeword at the fitted read voltage at the second side; and take the fitted read voltage at the second side as a reference read voltage at the second side according to the corresponding flip result at the fitted read voltage at the second side being within the preset interval.

For example, as shown in FIG. 14, the memory controller is configured to: obtain a fitted read voltage (xₕ) at the second side corresponding to the target flip result (yₕ) based on a reference read voltage (abscissa x_{g} corresponding to the point G) at the first side, a flip result (ordinate y_{g} corresponding to the point G) corresponding to the reference read voltage at the first side, a target flip result (yₕ) and a fourth mapping function, for example, obtain a fitted read voltage (xₕ) at the second side corresponding to the target flip result (yₕ) according to the coordinates of the point G, for example, obtain the point H (xₕ,yₕ) according to the coordinates of the point G, the target flip result (yₕ) and the fourth mapping function, wherein the fourth mapping function comprises the following equation (3):

$$x 2 = x 1 - \sqrt{\frac{y 1 - c}{a}} - \sqrt{\frac{y 2 - c}{a}}$$

Where x1 and y1 represent the abscissa and ordinate of the obtained actual point respectively, y2 represents the target flip result which is a random value in the reference preset interval, and x2 represents the fitted read voltage. The fourth mapping function is intended to obtain the fitted read voltage (for example, xₕ shown in FIG. 14) according to a value in the reference preset interval in combination with the obtained actual point (for example, the point G).

The coordinates of the point G, the target flip result (yₕ), the first parameter/adjusted first parameter, and the second parameter are substituted into the fourth mapping equation (3) to obtain the point H (xₕ,yₕ).

At this time, the point H (xₕ,yₕ) is a fitted point, the abscissa xₕ corresponding to the point H is the fitted read voltage at the second side, and the memory controller is configured to: take the fitted read voltage as a new target read voltage; obtain a corresponding flip result (yᵢ) of the at least one codeword at the fitted read voltage (xₕ) at the second side in the manner of obtaining the flip result in the foregoing example, for example, obtain the point I(xₕ,yᵢ), where the point I is the actual point; and take the fitted read voltage (xₕ) at the second side as a reference read voltage at the second side according to the corresponding flip result (ordinate yᵢ corresponding to the point I) at the fitted read voltage at the second side being within the preset interval.

In some examples, the memory controller is configured to: according to the corresponding flip result at the fitted read voltage at the second side being outside the preset interval, obtain a next fitted read voltage at the second side corresponding to the target flip result based on a last fitted read voltage at the second side, a flip result corresponding to the last fitted read voltage at the second side, the target flip result and the fifth mapping function, until the latest corresponding flip result at the fitted read voltage at the second side is within the preset interval, and take the latest fitted read voltage at the second side as a reference read voltage at the second side. The fifth mapping function is obtained according to the quadratic function model, the first parameter/the adjusted first parameter and the second parameter.

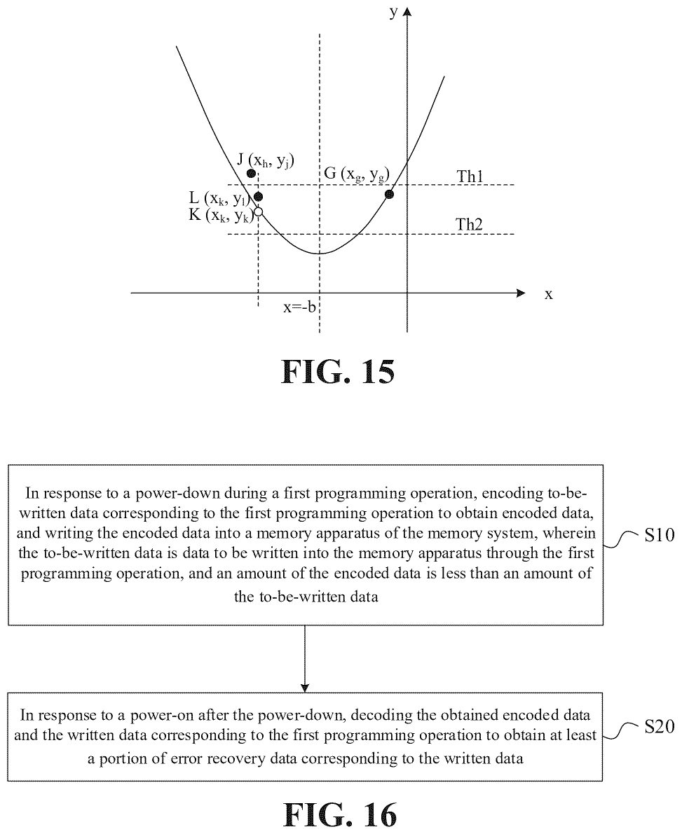

In some examples, as shown in FIG. 14 and FIG. 15, it is taking the fitted read voltage at the second side (the abscissa xₕ corresponding to the point H) as the new target read voltage, and obtaining the corresponding flip result (yⱼ) of the at least one codeword at the fitted read voltage (xₕ) at the second side in the manner of obtaining the flip result in the foregoing example, for example, obtaining the point J (xₕ,yⱼ). The peripheral circuit is further configured to: according to the corresponding flip result (the ordinate yⱼ of the point J) at the fitted read voltage at the second side being outside the preset interval, obtain a next fitted read voltage (xx) at the second side corresponding to the target flip result (yₖ) based on a last fitted read voltage (the abscissa xₕ of the point J) at the second side, a corresponding flip result (the ordinate yⱼ of the point J) at the last fitted read voltage at the second side, the target flip result (yₖ) and the fifth mapping function, for example, obtain the point K(xₖ,yₖ) shown in FIG. 15, until the latest corresponding flip result (yₗ) at the fitted read voltage (xₖ) at the second side is within the preset interval, e.g., until the ordinate of the point L (xₖ,yₗ) shown in FIG. 15 is within the preset interval, and take the latest fitted read voltage (xₖ) at the second side as a reference read voltage at the second side; the fifth mapping function is obtained according to the quadratic function model, the first parameter/the adjusted first parameter and the second parameter, wherein the fifth mapping function comprises the following relation (4):

$$x 2 = x 1 + \sqrt{\frac{y 1 - c}{a}} - \sqrt{\frac{y 2 - c}{a}}$$

Where x1 and y1 represent the abscissa and ordinate of the obtained actual point respectively, y2 represents the target flip result which is a random value in the reference preset interval, and x2 represents the fitted read voltage. The third mapping function is intended to obtain a fitted read voltage (for example, xx shown in FIG. 15) according to a value in the reference preset interval in combination with an obtained actual point (for example, the point J).

The coordinates of the point J, the target flip result (yₖ), the first parameter/the adjusted first parameter, and the second parameter are substituted into the equation (4) of the fifth mapping function to obtain the point K(xₖ,yₖ).

In this case, the point K(x_{K}, yₖ) is a fitted point, the abscissa xₕ corresponding to the point K is the fitted read voltage at the second side, and the memory controller is configured to: take the fitted read voltage as a new target read voltage, obtain a corresponding flip result (yₗ) of the at least one codeword at the fitted read voltage (xₖ) at the second side in the manner of obtaining the flip result in the foregoing example, for example, obtain the point L (xₖ,yₗ), where the point L is the actual point; and take the latest fitted read voltage (xₖ) at the second side as a reference read voltage at the second side according to the latest corresponding flip result (ordinate yₗ corresponding to the point L) at the fitted read voltage at the second side is within the preset interval.

It should be noted that the point A, the point B, the point D, the point H, and the point K in the examples of the present disclosure are fitted points, and located on the curve where the quadratic function model is located. The point C, the point E, the point F, the point G, the point I, the point J and the point L are actual points, and may or may not be located on the curve where the quadratic function model is located.

In the examples of the present disclosure, the M reference read voltages and the corresponding flip results at the M reference read voltages may be obtained by applying the method of obtaining the reference read voltage at the first side/the second side in the foregoing examples, and the prediction parameters are obtained based on the M reference read voltages and the M flip results.

In some examples, the first parameter is a variable and the second parameter is a constant. The memory controller is configured to: obtain a prediction parameter according to the M flip results and the M reference read voltages in combination with a quadratic function model; and take the prediction parameter as the predicted reference voltage.

For example, the N groups of prediction parameters may be obtained according to the M flip results, the M reference read voltages, the quadratic function model, and the second parameter, where N is equal to CM.

Here, the second parameter may be obtained when fitting the preset function model and stored in the memory device.

In some implementations, if M is equal to 2, N is equal to 1, and two reference read voltages and coordinates corresponding to the two flip results are substituted into a calculation formula (1) of b, so as to obtain b and to further obtain a set of prediction parameters. The prediction parameter is taken as the predicted reference voltage.

In some implementations, if M is greater than 2, N is equal to CM, and CM combinations of two reference read voltages and their corresponding two flip results may be obtained based on M reference read voltages and M flip results. CM sets of prediction parameters may be obtained based on the CM combinations in combination with calculation formula (1) of b. Outliers of the CM sets of prediction parameters are determined; and an outlier is determined based on the median and the standard deviation of the CM sets of prediction parameters, or both the maximum value and the minimum value of the CM sets of prediction parameters are taken as outliers. After the outliers are removed from the CM sets of prediction parameters, the median or the average value of the remaining prediction parameters is taken as the predicted reference voltage.

As such, by determining outliers of the plurality of sets of prediction parameters and removing the outliers, the accuracy and reliability are ensured in applying the remaining prediction parameters to determine the predicted reference voltage.

In some examples, both the first parameter and the second parameter are variables. The memory controller is configured to: obtain a prediction parameter according to the M flip results and the M reference read voltages in combination with the quadratic function model; take the prediction parameter as the target read voltage, and obtain a corresponding flip result of the at least one codeword when the prediction parameter is taken as the target read voltage; obtain a new prediction parameter according to the M flip results, the M reference read voltages, the prediction parameter, the corresponding flip result when the prediction parameter is taken as the target read voltage in combination with the quadratic function model; and take the new prediction parameter as the predicted reference voltage.

In some implementations, the second parameter is a variable, but an initial value of the second parameter may be obtained when fitting the preset function model, and stored in the memory device.

For example, the N sets of prediction parameters are obtained according to the M flip results, the M reference read voltages, the quadratic function model, the initial value of the second parameter in combination with the calculation formula (1) of b, where N is equal to CM.

In some implementations, if M is equal to 2, N is equal to 1, the two reference read voltages and the coordinates corresponding to the two flip results are substituted into the calculation formula (1) of b, in order to obtain b, and to further obtain a set of prediction parameters; the prediction parameters are taken as the target read voltage, the corresponding flip result of the at least one codeword at the prediction parameters being taken as the target read voltages is obtained, for example, one actual point is obtained at this time; next, the coordinates of the 3 actual points (the two reference read voltages and their two corresponding flip results, the prediction parameters, and the corresponding flip result when the prediction parameters being taken as the target read voltages) are substituted into the calculation formula (3) of b, so as to obtain b, and to further obtain a new set of prediction parameters, and the new prediction parameters are taken as the prediction reference voltage.

In this way, the new prediction parameter is further obtained by applying the prediction parameter and the corresponding flip result when the prediction parameter is taken as the read voltage, so that the accuracy of the obtained predicted reference voltage can be improved.

In some implementations, the M reference read voltages are on the same side of the axis of symmetry of the curve where the quadratic function model is located, for example, the M reference read voltages are all at the first side of the axis of symmetry of the curve where the quadratic function model is located, or the M reference read voltages are all on the second side of the axis of symmetry of the curve where the quadratic function model is located.

In some implementations, at least two of the M reference read voltages are on both sides of the axis of symmetry of the curve where the quadratic function model is located. The points located on both sides of the axis of symmetry of the curve where the quadratic function model is located are more representative, so that a wider data range can be covered, and the accuracy and reliability of determining the prediction parameters according to the reference read voltage to further obtain the predicted reference voltage can be improved.

It should be noted that, the target read voltage (the first read voltage) used for the first time may refer to a preset read voltage that can distinguish between two adjacent intermediate memory states of the memory cell of the memory device after the first programming operation in the past read process, where the preset read voltage may be an empirical value; or may be a default value configured when the memory device leaves the factory, and the default value is obtained through a large number of simulation experiments before the memory device leaves the factory.

The process of obtaining the target reference voltage of the at least one codeword is applicable to any one of the N pages.

According to the examples of the present disclosure, the amount of the transmitted data is reduced by transmitting the flip result (the size of the flip result may be a few bytes) instead of transmitting at least one codeword (for example, the size of the codeword may be 4 KB); the process of obtaining the flip result is converged inside the memory device, which for example, does not occupy the space of the memory controller, and is less dependent on the memory controller; according to the limited number of the reference reading voltages and the limited number of flip results within the preset interval, the process of obtaining the target reference voltage in combination with the preset function model is completed in the memory device, and since the preset interval is a reasonable interval determined when the preset function model is fitted, selecting the data within the preset interval for determining the target reference voltage can not only improve the accuracy of determining the target reference voltage, but also reduce the influence of the data noise to a certain extent, thus the reliability is improved, while the number of cycle iterations can be reduced, the speed of determining the target reference voltage when power-on after power-down is accelerated, the read operation is in turn performed on the written data by utilizing the target reference voltage, and the speed of re-performing the programming operation is accelerated.

According to a first aspect, in an example of the present disclosure, the to-be-written data corresponding to the first programming operation is encoded to obtain the encoded data, wherein an amount of the encoded data is less than an amount of the to-be-written data, and the encoded data is written into the memory device to obtain the error recovery data required for re-performing the programming operation when the power-on after the power-down. In this way, on the one hand, by reducing the amount of data written to the memory device during the power-down protection, the requirement on the capacity of the capacitor is effectively reduced; on the other hand, when the power-on after the power-down, at least part of the error recovery data is obtained by decoding the encoded data and the written data corresponding to the first programming operation, which can ensure the data integrity when the first programming operation process suffers from the power-down and reduce the risk of failure of the overall programming operation, thereby improving the reliability of the programming operation.

According to a second aspect, in an example of the present disclosure, an operating method of a memory system is provided, and FIG. 16 is a first flowchart of an operating method of a memory system according to an example of the present disclosure. As shown in FIG. 16, the operating method of the memory system comprises:

Operation S10: in response to a power-down during a first programming operation, encoding to-be-written data corresponding to the first programming operation to obtain encoded data; writing the encoded data into a memory device of the memory system, wherein the to-be-written data is data to be written into the memory device through the first programming operation, and an amount of the encoded data is less than an amount of the to-be-written data.

Operation S20: in response to a power-on after the power-down, decoding the obtained encoded data and the written data corresponding to the first programming operation to obtain at least a portion of error recovery data corresponding to the written data.

In some examples, the memory device comprises a plurality of memory cells each having N memory bits, wherein N memory bits of the memory cell correspond to N pages of data, N is an integer greater than 2, and the to-be-written data comprises data to be written into N pages; and the encoding the to-be-written data to be written into the memory device corresponding to the first programming operation comprises: performing a logical operation on data to be written into every two pages of N pages to obtain the encoded data.

In some examples, a ratio of the amount of the data to be written into N pages to the amount of the encoded data is N:N-1.

In some examples, the performing the logical operation on data to be written into every two pages of N pages to obtain the encoded data comprises: performing an OR logical operation or an AND logical operation on the data to be written into every two pages of N pages to obtain the encoded data; and the decoding the encoded data obtained from the memory device and the written data corresponding to the first programming operation comprises: performing an OR logical operation and an AND logical operation on the encoded data and the written data to obtain the at least the portion of error recovery data.

For example, the memory device comprises a plurality of memory cells with memory bits of four, wherein four memory bits of the memory cell correspond to data of four pages, and the to-be-written data comprises data to be written into four pages; and the memory controller is configured to: perform a logical operation on data to be written into every two pages of four pages to obtain the encoded data. Taking N equal to 4 as an example, a ratio of the amount of the data to be written into four pages to the amount of the encoded data is 4:3.

The logical operation are performed on data to be written into every two pages of four pages (LP, MP, UP, and XP) to obtain the encoded data. For example, the logical operation are performed on the data to be written into LP and the data to be written into MP to obtain first encoded data Parity 1, the logical operation are performed on the data to be written into MP and the data to be written into UP to obtain second encoded data Parity2, and the logical operation are performed on the data to be written into UP and the data to be written into XP to obtain third encoded data Parity3. It can be understood that, by performing the logical operation on data to be written into the four pages, three encoded data (the first encoded data Parity1, the second encoded data Parity2, and the third encoded data Parity3) are obtained.

In other examples, the logical operation are performed on the data to be written into LP and the data to be written into MP to obtain the first encoded data, the logical operation are performed on the data to be written into LP and the data to be written into UP to obtain the second encoded data, and the logical operation are performed on the data to be written into UP and the data to be written into XP to obtain the third encoded data.

In some examples, the method further comprises: controlling to disable an error correction encoding module in a memory controller of the memory system before writing the encoded data into the memory device; and controlling to disable an error correction decoding module in the memory controller after obtaining the encoded data from the memory device.

In some examples, as shown in FIG. 7, the memory controller 106 comprises an error correction encoding module 1065 and an error correction decoding module 1066, wherein the error correction encoding module 1065 is configured to encode the to-be-stored data to obtain check data, and the error correction decoding module 1066 is configured to decode the check data to detect and correct possible error data in a data transmission process.

For example, the operating method of the memory system further comprises: controlling to disable error correction encoding module 1065 before writing the encoded data into the memory device 104. Since the algorithm employed by the error correction encoding module (for example, the ECC error correction algorithm) is different from the principle of the logic operation for performing the logical operation on the to-be-written data to obtain the encoded data, encoding the encoded data generated by the logical operation again may cause the data structure originally dedicated to obtaining the encoded data of the error recovery data to be damaged, which may cause the failure of obtaining the error recovery data required to re-perform the programming operation when power-on after the power-down. In order to ensure the accuracy of the encoded data in obtaining the error recovery data required to re-perform the programming operation when power-on after the power-down, it is not necessary to perform error correction encoding on the encoded data here.

In some examples, the operating method of the memory system further comprises: control to disable error correction decoding module 1066 after obtaining the encoded data from the memory device 104. Similarly, in order to ensure the accuracy of the encoded data in obtaining the error recovery data required to re-perform the programming operation when power-on after the power-down, it is not necessary to perform error correction decoding on the encoded data here.

In some examples, the memory device comprises a plurality of memory cells each having N memory bits, wherein N is an integer greater than 2; the memory device comprises a first memory region, wherein the memory cells in the first memory region read or write a bit of data in a first mode; and a second memory region, wherein the memory cells in the second memory region read or write N bits of data in a second mode; and the writing the encoded data into the memory device of the memory system comprises: writing the encoded data into the memory device in the first mode; and the method further comprises: controlling the memory device to read the encoded data in the first mode before obtaining the encoded data from the memory device.

In some examples, the first mode may be understood as Single Level Read mode or Single Level Write mode. The second mode may be understood as a Multi-Level Read mode or a Multi-Level Write mode.

In some examples, writing the encoded data into the memory device of the memory system comprises: writing the encoded data into the memory device 104 in a Single Level Write mode.

In some examples, writing the encoded data into the memory device of the memory system comprises: controlling the memory device 104 to read the encoded data in a Single Level Read mode before obtaining the encoded data from the memory device 104.

According to the examples of the present disclosure, the speed of the first mode is fast and the operation is simple, and writing the encoded data into the memory device in the first mode when power-down can safely store the encoded data in the memory device in time, thus reducing the risk of data loss. When power-on after power-down, before obtaining the encoded data from the memory device, controlling the memory device to read the encoded data in the first mode helps to increase the speed of obtaining the error recovery data required to re-perform the programming operation, and the overall time of the programming operation is reduced.

In addition, by dividing the memory region of the memory device into a first memory area configured to store encoded data with high reliability requirements and a second memory area configured to store regular data with high capacity demand, and using different modes (the first mode and the second mode) for write operation and read operation in the first memory area and the second memory area, the memory space can be fully utilized and the performance of the memory device can be effectively optimized.

In some examples, the method further comprises: controlling the memory device to re-perform a programming operation with the error recovery data.

By decoding the encoded data and the written data corresponding to the first programming operation to obtain at least a portion of the error recovery data, it can ensure the data integrity when the first programming operation process suffers from the power-down, and re-performing the programming operation with the error recovery data can reduce the risk of failure of the overall programming operation and improve the reliability of the programming operation.

In some examples, the memory device comprises a plurality of memory cells that is to be programmed to an intermediate memory state after a first programming operation is performed, and data in the intermediate memory state is programmed to a target memory state after performing a second programming operation, and wherein a threshold voltage distribution width of the intermediate memory state is greater than a threshold voltage distribution width of the target memory state.

Here, the first programming operation may be referred to as a coarse programming operation, and the second programming operation may be referred to as a fine programming operation. Taking the QLC memory cell as an example, the threshold voltage distribution width of the QLC memory cell after the first programming operation is shown in FIG. 6A, and the threshold voltage distribution width of the QLC memory cell on which the first programming operation has been performed after the second programming operation is shown in FIG. 6B. For example, the threshold voltage distribution width of the intermediate memory state as shown in FIG. 6A is greater than the threshold voltage distribution width of the target memory state shown in FIG. 6B.

In some examples, the method further comprises: obtaining the to-be-written data from the memory device before encoding the to-be-written data; and obtaining the encoded data and the written data from the memory device before decoding the encoded data and the written data.

In some examples, the method further comprises: obtaining original to-be-written data from a buffer of the memory controller of the memory system before obtaining the to-be-written data; and sending the original to-be-written data to a page buffer of the memory device where the to-be-written data corresponding to the first programming operation is generated.

The complete flow of writing data into the memory cell of the memory device and reading data is simulated by sending the original to-be-written data to the page buffer and reading the original to-be-written data, which may simulate whether errors or data damage occurs in the data writing and reading processes, and the accuracy is higher when the to-be-written data obtained by the memory controller represents the reading result corresponding to the data actually written into the memory device during the first programming operation process. In addition, the speed of writing the data into the page buffer and reading the data is high, the power consumption is low, and it would not occupy excessive resources for power loss protection.

In some examples, the method further comprises: obtaining a target read voltage corresponding to the first programming operation before obtaining the written data; and control the memory device to perform a read operation on the written data with the target read voltage.

It should be noted that, the target reference voltage herein is the optimal read voltage found by the method in the examples of the present disclosure, and the target reference voltage may be applied to accurately perform the read operation on the written data, and the accuracy of the read result (the written data) is improved. The manner in which the target reference voltage is obtained will be further described below.

In some examples, the obtaining a target read voltage corresponding to the first programming operation comprises: obtaining M flip results at M reference read voltages corresponding to at least one codeword formed by a preset number of memory cells, wherein each of the flip results indicates the number of flipped bits of the at least one codeword in two read results at a first and second read voltage, wherein a difference between the first and second read voltage is less than a preset voltage, and M is an integer greater than or equal to 2; obtaining a predicted valley voltage according to the M flip results and the M reference read voltages in combination with a preset function model, wherein the preset function model represents a relationship between the flip results and the reference read voltages, and the M flip results are all within a preset interval; and determining the target read voltage based on the predicted valley voltage.

In some examples, the preset function model comprises a quadratic function model, and the quadratic function model comprises the following function relational expressions:

$$y = {a ( x + b )}^{2} + c$$

Where y is the flip result, x is the reference read voltage, b is to represent a prediction parameter, a is a first parameter, and c is a second parameter.

A manner in which the target reference voltage is obtained may refer to related descriptions in FIGS. 10 to 15, and details are not described herein again.

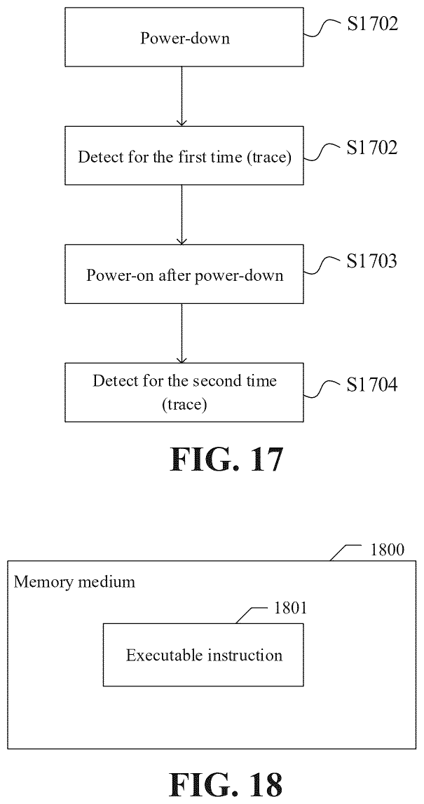

FIG. 17 is a second flowchart of an operating method of a memory system according to an example of the present disclosure. As shown in FIG. 17, by applying the operating method of the memory system according to an example of the present disclosure, the power-down protection process after power-down during the first programming operation and the data recovery process when power-on after power-down are verified. As shown in FIG. 17, the following operations are performed:

Operation S1701: power-down. Here, the power-down may be understood as abruptly powering off the memory system during the first program operation, e.g., unplugging the power supply.

Operation S1702: detecting a log for the first time (Trace). Here, the detecting the log may be understood as at least detecting an event log of the tracer during performance of the power down protection by the tracer.

In the detection of operation S1702, it can be found that during the whole process, data with an amount of (N-1) pages is written into the memory device in a first mode (for example, a Single Level Write mode), where N is a number of memory bits of the memory cell.

Operation S1703: power-on after power-down. Here, the power-on may be understood as powering on the memory system.

Operation S1704: detecting the log for the second time. Here, the detection of the log may be understood as at least detecting an event log of the tracer during performance of read scrub operation by the tracer.

In the detection of operation S1704, it can be found that during the whole process: 1), the query of the target reference voltage is performed; 2), the read operation is performed on the written data corresponding to the first programming operation with the target reference voltage to obtain a read result; and 3), error data recovery is performed according to the read result of the written data.

According to a third aspect of the present disclosure, a memory medium storing executable instructions thereon is provided, the executable instructions, when executed, implement the operations of the operating method according to the examples of the present disclosure.

In some examples, the memory medium may be a magnetic random access memory (FRAM), a read-only memory (ROM), a programmable read-only memory (PROM), an erasable programmable read-only memory (EPROM), an electrically erasable programmable read-only memory (EEPROM), a flash memory, a magnetic surface memory, an optical disk, or a compact disc read-only memory (CD-ROM), or the like; or may be various devices comprising one or any combination of the foregoing memory devices.

In some examples, the executable instructions may be written in the form of a program, software, software module, script, or code, may be written in any form of programming language (comprising compiled or interpreted languages, or declarative or procedural languages), and may be deployed in any form, comprising being deployed as a standalone program or as a module, component, subroutine, or other unit suitable for use in a computing environment.

As an example, executable instructions may, but not necessarily, correspond to files in a file system, may be stored in a portion of a file that stores other programs or data, for example, in one or more scripts stored in a hypertext markup language (HTML) document, in a single file dedicated to the program in question, or in multiple collaborative files (e.g., files that store one or more modules, subroutines, or portions of code).

As an example, executable instructions may be deployed for execution on one electronic device, or on multiple electronic devices located at one place, or alternatively on multiple electronic devices distributed at multiple places and interconnected by a communication network.

FIG. 18 is a schematic block diagram of a memory medium according to an example of the present disclosure. According to an example of the present disclosure, a memory medium 1800 storing executable instructions 1801 thereon is provided, the executable instructions 1801, when executed, may implement the operating method of the memory system in the foregoing technical solutions. The operating method comprises: in response to a power-down during a first programming operation, encoding to-be-written data corresponding to the first programming operation to obtain the encoded data; writing the encoded data into a memory device of the memory system, wherein the to-be-written data is data to be written into the memory device through the first programming operation, and an amount of the encoded data is less than an amount of the to-be-written data; and in response to a power-on after the power-down, decoding the obtained encoded data and the written data corresponding to the first programming operation to obtain at least a portion of error recovery data corresponding to the written data.

It should be understood that “one example” or “an example” mentioned throughout the specification means that a specific feature, structure, or characteristic related to the example is included in at least one example of the present disclosure. Thus, “in one example” or “in an example” appearing throughout the specification may not necessarily refer to the same example. Further, these particular features, structures, or characteristics may be incorporated in one or more examples in any suitable manner. It should be understood that, in various examples of the present disclosure, the sequence numbers of the foregoing processes do not mean a sequence of execution sequences, and an execution sequence of each process should be determined by function and intrinsic logic thereof, and should not constitute any limitation on an implementation process of the examples of the present disclosure. The foregoing sequence numbers of the examples of the present disclosure are merely for description, and do not represent the advantages or disadvantages of the examples.

The above description is only an example implementation of the present disclosure, and is not intended to limit the scope of the present disclosure, and any equivalent structural transformation made by using the present disclosure and the accompanying drawings or any direct/indirect application of the present disclosure to other related technical fields is included within the scope of the present disclosure.

What is claimed is:

1. A memory system, comprising:
a memory device; and
a memory controller coupled to the memory device and configured to:
in response to a power-down during a first programming operation, encode to-be-written data corresponding to the first programming operation to obtain encoded data, and write the encoded data into the memory device, wherein the to-be-written data comprises data to be written into the memory device with the first programming operation, and an amount of the encoded data is less than an amount of the to-be-written data; and
in response to a power-on after the power-down, decode the obtained encoded data and the written data corresponding to the first programming operation to obtain at least a portion of error recovery data corresponding to the written data.

2. The memory system of claim 1, wherein the memory device comprises memory cells each comprises N memory bits, N memory bits of a memory cell of the memory cells correspond to N pages of data, N is an integer greater than 2, and the to-be-written data comprises data to be written into N pages; and
the memory controller is configured to: perform a logical operation on data to be written into every two pages of N pages to obtain the encoded data.

3. The memory system of claim 2, wherein a ratio of an amount of the data to be written into N pages to the amount of the encoded data is N:N-1.

4. The memory system of claim 2, wherein the memory controller is configured to:
perform an OR logical operation or an AND logical operation on the data to be written into every two pages of the N pages to obtain the encoded data; and
perform an OR logical operation and an AND logical operation on the encoded data and the written data to obtain at least the portion of the error recovery data.

5. The memory system of claim 1, wherein the memory controller comprises an error correction encoding module and an error correction decoding module; and
the memory controller is configured to:
control to disable the error correction encoding module before writing the encoded data into the memory device; and
control to disable the error correction decoding module after obtaining the encoded data from the memory device.

6. The memory system of claim 1, wherein the memory device comprises:
memory cells each having N memory bits, wherein N is an integer greater than 2;
a first memory region, wherein the memory cells in the first memory region read or write a bit of data in a first mode; and
a second memory region, wherein the memory cells in the second memory region read or write N bits of data in a second mode; and
the memory controller is configured to:
write the encoded data into the memory device in the first mode; and
control the memory device to read the encoded data in the first mode before obtaining the encoded data from the memory device.

7. The memory system of claim 1, wherein the memory controller is further configured to:
control the memory device to re-perform a programming operation with the error recovery data.

8. The memory system of claim 1, wherein the memory device comprises memory cells that are to be programmed to an intermediate memory state after the first programming operation is performed, data in the intermediate memory state are to be programmed to a target memory state after a second programming operation is performed, and wherein a threshold voltage distribution width of the intermediate memory state is greater than a threshold voltage distribution width of the target memory state.

9. The memory system of claim 8, wherein the memory controller is configured to:
obtain the to-be-written data from the memory device before encoding the to-be-written data; and
obtain the encoded data and the written data from the memory device before decoding the encoded data and the written data.

10. The memory system of claim 9, wherein the memory device comprises a page buffer, and the memory controller comprises a buffer and is configured to:
obtain original to-be-written data from the buffer before obtaining the to-be-written data; and
send the original to-be-written data to the page buffer to generate the to-be-written data corresponding to the first programming operation in the page buffer.

11. The memory system of claim 9, wherein the memory controller is configured to:
obtain a target reference voltage corresponding to the first programming operation before obtaining the written data; and
control the memory device to perform a read operation on the written data with the target reference voltage.

12. The memory system of claim 11, wherein the memory controller is configured to:
obtain M flip results at M reference read voltages corresponding to at least one codeword formed by a preset number of memory cells, wherein each of the flip results indicates a number of flipped bits of the at least one codeword in two read results at a first and second read voltage, a difference between the first and second read voltage is less than a preset voltage, and M is an integer greater than or equal to 2;
obtain a predicted valley voltage according to the M flip results and the M reference read voltages in combination with a preset function model, wherein the preset function model represents a relationship between the flip results and the reference read voltages, and the M flip results are all within a preset interval; and
determine the target reference voltage based on the predicted valley voltage.

13. The memory system of claim 12, wherein the preset function model comprises a quadratic function model comprising a following functional relation:
y=a(x+b)²+c
wherein y comprises a flip result of the M flip results, x comprises a reference read voltage of the M reference read voltages, b represents a prediction parameter, a comprises a first parameter, and c comprises a second parameter.

14. An operating method of a memory system, comprising:
in response to a power-down during a first programming operation, encoding to-be-written data corresponding to the first programming operation to obtain encoded data, and writing the encoded data into a memory device of the memory system, wherein the to-be-written data is data to be written into the memory device with the first programming operation, and an amount of the encoded data is less than an amount of the to-be-written data; and
in response to a power-on after the power-down, decoding the obtained encoded data and the written data corresponding to the first programming operation to obtain at least a portion of error recovery data corresponding to the written data.

15. The operating method of claim 14, wherein the memory device comprises a memory cells each having N memory bits, N memory bits of the memory cell correspond to N pages of data, N is an integer greater than 2, and the to-be-written data comprises data to be written into N pages; and
the encoding the to-be-written data to be written into the memory device corresponding to the first programming operation comprises:
performing a logical operation on data to be written into every two pages of N pages to obtain the encoded data.

16. The operating method of claim 15, wherein a ratio of an amount of the data to be written into N pages to the amount of the encoded data is N:N-1.

17. The operating method of claim 15, wherein
the performing the logical operation on the data to be written into every two pages of the N pages to obtain the encoded data comprises:
performing an OR logical operation or an AND logical operation on the data to be written into every two pages of the N pages to obtain the encoded data; and
the decoding the encoded data obtained from the memory device and the written data corresponding to the first programming operation comprises:
performing an OR logical operation and an AND logical operation on the encoded data and the written data to obtain at least the portion of the error recovery data.

18. The operating method of claim 14, further comprising:
controlling to disable an error correction encoding module in a memory controller of the memory system before writing the encoded data into the memory device; and
controlling to disable an error correction decoding module in the memory controller after obtaining the encoded data from the memory device.

19. The operating method of claim 14, wherein the memory device comprises:
a memory cells each having N memory bits, N being an integer greater than 2;
a first memory region, wherein memory cells in the first memory region read or write a bit of data in a first mode; and
a second memory region, wherein memory cells in the second memory region read or write N bits of data in a second mode; and
the writing the encoded data into the memory device of the memory system comprises:
writing the encoded data into the memory device in the first mode; and the method further comprises:
controlling the memory device to read the encoded data in the first mode before obtaining the encoded data from the memory device.

20. A memory medium storing executable instructions thereon, wherein the executable instructions, when executed, implement an operating method of a memory system, comprising:
in response to a power-down during a first programming operation, encoding to-be-written data corresponding to the first programming operation to obtain encoded data, and writing the encoded data into a memory device of the memory system, wherein the to-be-written data is data to be written into the memory device with the first programming operation, and an amount of the encoded data is less than an amount of the to-be-written data; and
in response to a power-on after the power-down, decoding the obtained encoded data and the written data corresponding to the first programming operation to obtain at least a portion of error recovery data corresponding to the written data.
